(19) United States
(12) Patent Application Publication
(10) Pub. No.: US 2025/0175199 A1
(43) Pub. Date: May 29, 2025

(54) HIGH FREQUENCY MODULE AND COMMUNICATION DEVICE

(71) Applicant: Murata Manufacturing Co., Ltd., Nagaokakyo-shi (JP)

(72) Inventors: Nanami YUMURA, Nagaokakyo-shi (JP); Takanori UEJIMA, Nagaokakyo-shi (JP); Shogo YANASE, Nagaokakyo-shi (JP); Yuusuke KISHI, Nagaokakyo-shi (JP); Masaki TADA, Nagaokakyo-shi (JP); Mizuki KINOSHITA, Nagaokakyo-shi (JP); Ryoya SHIOMI, Nagaokakyo-shi (JP)

(73) Assignee: Murata Manufacturing Co., Ltd., Nagaokakyo-shi (JP)

(21) Appl. No.: 18/909,979

(22) Filed: Oct. 9, 2024

(30) Foreign Application Priority Data
Nov. 28, 2023 (JP) 2023-201122

(51) Int. Cl. H04B 1/00; H04B 1/16; H04B 1/18

(52) U.S. Cl. CPC H04B 1/006; H04B 1/1607; H04B 1/18

(57) ABSTRACT

A high frequency module includes a mounting substrate, a first electronic component, a second electronic component, a third electronic component, and a side surface shield electrode. The mounting substrate has a first main surface and a second main surface which face each other. The first electronic component is disposed on the first main surface. The second electronic component is disposed on the first main surface. The third electronic component is disposed between the first electronic component and the second electronic component on the first main surface. The side surface shield electrode is provided on at least one side surface of the third electronic component. The mounting substrate includes a ground layer. The side surface shield electrode is connected to the ground layer.

### CROSS-REFERENCE TO RELATED APPLICATION

The present application claims priority to Japanese Application No. JP2023-201122, filed in Japan on Nov. 28, 2023, the contents of which are incorporated by reference in its entirety.

### BACKGROUND

### 1. Field

The present disclosure relates to a high frequency module and a communication device which include a third electronic component disposed between a first electronic component and a second electronic component.

### 2. Description of the Related Art

A high frequency module described in International Publication No. 2022/102288 includes a module substrate (mounting substrate), a transmission filter (first electronic component), a reception filter (second electronic component), and a metal shield wall. The transmission filter and the reception filter are disposed on one main surface of the module substrate. The metal shield wall is disposed between the transmission filter and the reception filter on the one main surface of the module substrate. The metal shield wall reduces interference of the electromagnetic waves (signals) between the transmission filter and the reception filter by reducing a leakage of electromagnetic waves propagating from the transmission filter to the reception filter.

### SUMMARY

In a configuration described in International Publication No. 2022/102288, the metal shield wall needs to be disposed between the transmission filter and the reception filter. Consequently, there is a problem in that a size of the high frequency module increases.

In view of the above-described problems, an exemplary embodiment of the present disclosure is to provide a high frequency module and a communication device which can reduce interference of electromagnetic waves between a first electronic component and a second electronic component and which can achieve size reduction.

A high frequency module according to an aspect of the present disclosure includes a mounting substrate, a first electronic component, a second electronic component, a third electronic component, and a side surface shield electrode. The mounting substrate has a first main surface and a second main surface which face each other. The first electronic component is disposed on the first main surface of the mounting substrate. The second electronic component is disposed on the first main surface of the mounting substrate. The third electronic component is disposed between the first electronic component and the second electronic component on the first main surface of the mounting substrate. The side surface shield electrode is provided on at least one side surface of the third electronic component. The mounting substrate includes a ground layer. The side surface shield electrode is connected to the ground layer.

A communication device according to an aspect of the present disclosure includes the high frequency module and a signal processing circuit. The signal processing circuit is connected to the high frequency module to perform signal processing on a high frequency signal.

According to a high frequency module and a communication device in the present disclosure, there is an advantage in that interference of a signal between a first electronic component and a second electronic component can be reduced and size reduction can be achieved.

### BRIEF DESCRIPTION OF THE DRAWINGS

FIG. 1 is a block diagram of a high frequency module and a communication device according to Embodiment 1;

FIG. 2 is a cross-sectional view of the high frequency module according to Embodiment 1;

FIG. 3 is a cross-sectional view of a third electronic component provided in the high frequency module according to Embodiment 1;

FIG. 4 is a cross-sectional view of a high frequency module according to Embodiment 2;

FIG. 5 is a cross-sectional view of a high frequency module according to Modification Example 3 of Embodiment 2;

FIG. 6 is a cross-sectional view of a high frequency module according to Modification Example 4 of Embodiment 2;

FIG. 7 is a cross-sectional view of a high frequency module according to Embodiment 3;

FIG. 8 is a cross-sectional view of a high frequency module according to Embodiment 4;

FIG. 9 is a cross-sectional view of a high frequency module according to Modification Example 1 of Embodiment 4;

FIG. 10 is a cross-sectional view of a high frequency module according to Modification Example 2 of Embodiment 4;

FIG. 11 is a perspective plan view of a portion of an outer shield electrode in a high frequency module according to Embodiment 5;

FIG. 12 is a perspective plan view of a portion of an outer shield electrode in a high frequency module according to Embodiment 6;

FIG. 13 is a perspective plan view of a portion of an outer shield electrode in a high frequency module according to Modification Example 1 of Embodiment 6;

FIG. 14 is a perspective plan view of a portion of an outer shield electrode in a high frequency module according to Embodiment 7; and

FIG. 15 is a cross-sectional view of a high frequency module according to Embodiment 8.

### DETAILED DESCRIPTION

### Embodiment 1

A high frequency module 1 and a communication device 30 according to Embodiment 1 will be described in detail with reference to the drawings.

### (1) Overview

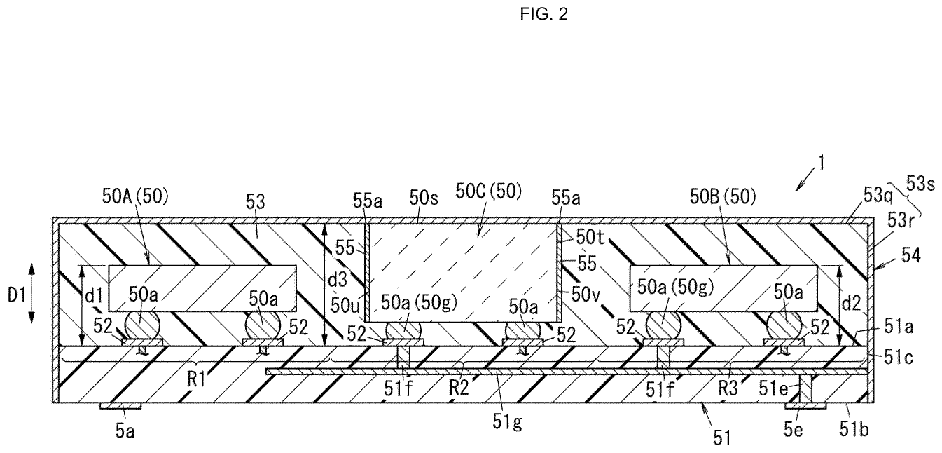

As shown in FIG. 2, the high frequency module 1 according to Embodiment 1 includes a mounting substrate 51, a first electronic component 50A, a second electronic component 50B, a third electronic component 50C, and a side surface shield electrode 55. The mounting substrate 51 has a first main surface 51a and a second main surface 51b which face each other. The first electronic component 50A is disposed on the first main surface 51a of the mounting substrate 51. The second electronic component 50B is disposed on the first main surface 51a of the mounting substrate 51. The third electronic component 50C is disposed between the first electronic component 50A and the second electronic component 50B on the first main surface 51a of the mounting substrate 51. The side surface shield electrode 55 is provided on at least one side surface of the third electronic component 50C. The mounting substrate 51 includes a ground layer 51g. The side surface shield electrode 55 is connected to the ground layer 51g of the mounting substrate 51.

According to this configuration, interference of electromagnetic waves (signals) between the first electronic component 50A and the second electronic component 50B can be reduced by the side surface shield electrode 55 provided on an outer peripheral surface 50t of the third electronic component 50C. In addition, the side surface shield electrode 55 is disposed by using the outer peripheral surface 50t of the third electronic component 50C. Therefore, it is not necessary to secure a disposition space for disposing a shield wall on the first main surface 51a of the mounting substrate 51, compared to a case that the shield wall is disposed separately from the third electronic component 50C. As a result, the high frequency module 1 can achieve size reduction. According to the above-described configuration, the interference of the electromagnetic waves between the first electronic component 50A and the second electronic component 50B can be reduced, and the high frequency module 1 can achieve the size reduction.

### (2) Configuration of Communication Device

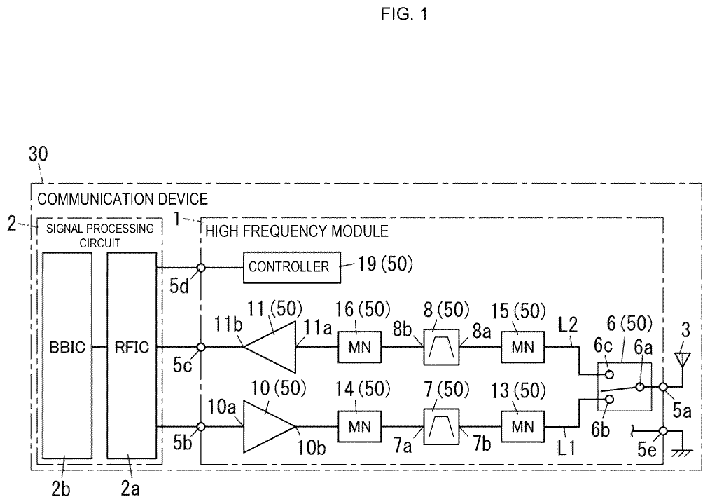

As shown in FIG. 1, the communication device 30 is a communication device including the high frequency module 1. For example, the communication device 30 is a mobile terminal (for example, a smartphone). Without being limited thereto, for example, the communication device 30 may be a wearable terminal (for example, a smartwatch). For example, the high frequency module 1 is a module compatible with a fourth generation mobile communication (4G) standard and a fifth generation mobile communication (5G) standard. For example, the 4G standard is Third Generation Partnership Project (3GPP, registered trademark) or Long Term Evolution (LTE, registered trademark) standard. For example, the 5G standard is 5G New Radio (NR).

The communication device 30 includes a signal processing circuit 2 and an antenna 3 in addition to the high frequency module 1.

The high frequency module 1 is configured to amplify a reception signal (high frequency signal) received by the antenna 3 and to output the amplified reception signal to the signal processing circuit 2. In addition, the high frequency module 1 is configured to amplify a transmission signal (high frequency signal) output from the signal processing circuit 2 and to transmit the amplified transmission signal from the antenna 3. The high frequency module 1 is controlled by the signal processing circuit 2, for example.

The signal processing circuit 2 is connected to the high frequency module 1, and is configured to perform signal processing on the reception signal output from the high frequency module 1. The signal processing circuit 2 is configured to perform the signal processing on the transmission signal to be output to the high frequency module 1. The signal processing circuit 2 includes a radio frequency (RF) signal processing circuit 2a and a baseband signal processing circuit 2b.

For example, the RF signal processing circuit 2a is a radio frequency integrated circuit (RFIC), and performs the signal processing on the high frequency signal (transmission signal and reception signal). The RF signal processing circuit 2a performs the signal processing such as down-conversion on the reception signal output from the high frequency module 1, and outputs the processed reception signal to the baseband signal processing circuit 2b. In addition, the RF signal processing circuit 2a performs the signal processing such as up-conversion on the transmission signal output from the baseband signal processing circuit 2b, and outputs the processed transmission signal to the high frequency module 1.

For example, the baseband signal processing circuit 2b is a baseband integrated circuit (BBIC). The baseband signal processing circuit 2b outputs the reception signal output from the RF signal processing circuit 2a to the outside. For example, the output signal (reception signal) is used for image display as an image signal or is used for communication as an audio signal. In addition, the baseband signal processing circuit 2b generates the transmission signal from a baseband signal (for example, the audio signal and the image signal) input from the outside, and outputs the generated transmission signal to the RF signal processing circuit 2a.

### (3) Configuration of High Frequency Module

As shown in FIG. 1, the high frequency module 1 includes a plurality of outer terminals 5a to 5e, a plurality of electronic components 50, and a plurality of signal paths (in the example in FIG. 1, a first signal path L1 and a second signal path L2). In the example in FIG. 1, the plurality of electronic components 50 include a switch 6, a transmission filter 7, a reception filter 8, a power amplifier 10, a low noise amplifier 11, matching circuits 13 to 16, and a controller 19.

The outer terminal 5a is an antenna terminal to which the antenna 3 is connected. The outer terminal 5b is connected to an output unit of the signal processing circuit 2, and is an input terminal to which the transmission signal output from the output unit of the signal processing circuit 2 is input. The outer terminal Sc is connected to an input unit of the signal processing circuit 2, and is an output terminal that outputs the reception signal processed by the high frequency module 1 to the input unit of the signal processing circuit 2. The outer terminal 5d is connected to a signal output unit of the signal processing circuit 2, and is a signal input terminal which inputs a control signal for controlling the controller 19 from the signal processing circuit 2. The outer terminal 5e is a terminal for maintaining a ground potential of each ground electrode of the plurality of electronic components 50. The outer terminal 5e is electrically connected to the ground, and is maintained at the ground potential. Each ground electrode of the plurality of electronic components 50 is electrically connected to the outer terminal 5e such that each ground electrode of the plurality of electronic components 50 is maintained at the ground potential.

The description of “A is connected to B” is not limited to a case where A is in direct contact with B, and also includes a case where A is indirectly in contact with B with a conductive member interposed therebetween. In addition, the description of “A is electrically connected to B” means that A and B are connected to be conductive.

The switch 6 selects at least one signal path from the first signal path L1 and the second signal path L2, and connects the selected communication path to the antenna 3. The switch 6 is operated by a control signal from the controller 19. For example, the switch 6 is a switch integrated circuit (IC). The switch 6 includes a common terminal 6a, a first selection terminal 6b, and a second selection terminal 6c. The common terminal 6a can be selectively connected to at least one of the first selection terminal 6b and the second selection terminal 6c. The common terminal 6a is connected to the outer terminal 5a. The first selection terminal 6b is connected to the first signal path L1. The second selection terminal 6c is connected to the second signal path L2.

The first signal path L1 is a communication path that connects the first selection terminal 6b and the outer terminal 5b. In the first signal path L1, an output signal of the outer terminal 5b is transmitted to the first selection terminal 6b. The second signal path L2 is a communication path that connects the second selection terminal 6c and the outer terminal 5c. In the second signal path L2, an output signal of the second selection terminal 6c is transmitted to the outer terminal 5c.

The transmission filter 7 has a transmission band (communication band) including a first communication band as a pass band. The transmission filter 7 is provided in the first signal path L1. That is, the transmission filter 7 is connected between the first selection terminal 6b of the switch 6 and the outer terminal 5b.

The transmission filter 7 includes an input unit 7a and an output unit 7b. The input unit 7a is connected to an output unit 10b of the power amplifier 10 with a matching circuit 14 interposed therebetween. The output unit 7b is connected to the first selection terminal 6b of the switch 6 with a matching circuit 13 interposed therebetween. The transmission filter 7 causes an input signal (transmission signal) input to the input unit 7a to pass therethrough by limiting the input signal to a signal in a transmission band of the first communication band, and outputs the passing transmission signal from the output unit 7b.

The reception filter 8 has a reception band (communication band) including a second communication band as a pass band. The second communication band may be a communication band that at least partially overlaps the first communication band, or may be a communication band that does not overlap the first communication band at all. The reception filter 8 is provided in the second signal path L2. That is, the reception filter 8 is connected between the second selection terminal 6c of the switch 6 and the outer terminal Sc.

The reception filter 8 includes an input unit 8a and an output unit 8b. The input unit 8a is connected to the second selection terminal 6c of the switch 6 with a matching circuit 15 interposed therebetween. The output unit 8b is connected to an input unit 11a of the low noise amplifier 11 with a matching circuit 16 interposed therebetween. The reception filter 8 causes the input signal (reception signal) input to the input unit 7a to pass therethrough by limiting the input signal to a signal in a reception band of a third communication band, and outputs the passing reception signal from the output unit 8b.

For example, the transmission filter 7 and the reception filter 8 are acoustic wave filters including a piezoelectric substrate. More specifically, for example, the transmission filter 7 and the reception filter 8 are a surface acoustic wave (SAW) filter, a bulk acoustic wave (BAW) filter, or a film bulk acoustic resonator (FBAR) filter.

The power amplifier 10 is provided between the input unit 7a of the transmission filter 7 and the outer terminal 5b in the first signal path L1. The power amplifier 10 includes an input unit 10a and an output unit 10b. The input unit 10a is connected to the outer terminal 5b. The output unit 10b is connected to the input unit 7a of the transmission filter 7 with the matching circuit 14 interposed therebetween. The power amplifier 10 amplifies the transmission signal input to the input unit 10a, and outputs the amplified transmission signal from the output unit 10b to the input unit 7a of the transmission filter 7 with the matching circuit 14 interposed therebetween.

The low noise amplifier 11 is provided between the output unit 8b of the reception filter 8 and the outer terminal 5c in the second signal path L2. The low noise amplifier 11 includes the input unit 11a and an output unit 11b. The input unit 11a is connected to the output unit 8b of the reception filter 8 with the matching circuit 16 interposed therebetween. The output unit 11b is connected to the outer terminal 5c. The low noise amplifier 11 amplifies the reception signal input to the input unit 11a, and outputs the amplified reception signal from the output unit 11b to the outer terminal 5c.

The matching circuit 13 is provided between the first selection terminal 6b of the switch 6 and the transmission filter 7 in the first signal path L1. The matching circuit 13 is a circuit for impedance matching between the switch 6 and the transmission filter 7. For example, the matching circuit 13 includes an inductor connected in series to the first signal path L1 or an inductor connected between the first signal path L1 and the ground.

The matching circuit 14 is provided between the transmission filter 7 and the power amplifier 10 in the first signal path L1. The matching circuit 14 is a circuit for impedance matching between the transmission filter 7 and the power amplifier 10. For example, the matching circuit 14 includes the inductor connected in series to the first signal path L1 or the inductor connected between the first signal path L1 and the ground.

The matching circuit 15 is provided between the second selection terminal 6c of the switch 6 and the reception filter 8 in the second signal path L2. The matching circuit 15 is a circuit for impedance matching between the switch 6 and the reception filter 8. For example, the matching circuit 15 includes an inductor connected in series to the second signal path L2 or an inductor connected between the second signal path L2 and the ground.

The matching circuit 16 is provided between the reception filter 8 and the low noise amplifier 11 in the second signal path L2. The matching circuit 16 is a circuit for impedance matching between the reception filter 8 and the low noise amplifier 11. For example, the matching circuit 16 includes the inductor connected in series to the second signal path L2 or the inductor connected between the second signal path L2 and the ground.

The controller 19 controls the electronic components (for example, the switch 6, the power amplifier 10, the low noise amplifier 11, and the like) provided in the high frequency module 1 in accordance with a control signal from the signal processing circuit 2. The controller 19 is electrically connected to each of the electronic components. In addition, the controller 19 is connected to the signal output unit of the signal processing circuit 2 with the outer terminal 5d interposed therebetween. The controller 19 controls each of the electronic components in accordance with the control signal input to the outer terminal 5d from the signal output unit of the signal processing circuit 2.

### (4) Operation

An operation of the high frequency module 1 will be described.

In a case of transmission of the high frequency module 1, the common terminal 6a of the switch 6 is selectively connected to the first selection terminal 6b. In this manner, the transmission signal processed by the signal processing circuit 2 is input from the signal processing circuit 2 to the outer terminal 5b. The transmission signal input to the outer terminal 5b is output to the first selection terminal 6b of the switch 6 by passing through the power amplifier 10, the matching circuit 14, the transmission filter 7, and the matching circuit 13 in this order. In this case, the transmission signal is amplified by the power amplifier 10, and is limited to the signal in the first communication band by the transmission filter 7. The transmission signal is output from the first selection terminal 6b to the outer terminal 5a with the common terminal 6a interposed therebetween, and is transmitted to the outside from the antenna 3.

In a case of reception of the high frequency module 1, the common terminal 6a of the switch 6 is selectively connected to the second selection terminal 6c. In this manner, the reception signal received by the antenna 3 flows from the common terminal 6a to the second selection terminal 6c. The reception signal is output to the outer terminal Sc by passing through the matching circuit 15, the reception filter 8, the matching circuit 16, and the low noise amplifier 11 in this order. In this case, the reception signal is limited to the signal in the second communication band by the reception filter 8, and is amplified by the low noise amplifier 11. The reception signal is output from the outer terminal Sc to the signal processing circuit 2.

### (5) Example of Structure of High Frequency Module

As shown in FIG. 2, the high frequency module 1 further includes the mounting substrate 51, the plurality of pad electrodes 52, the resin member 53, the outer shield electrode 54, and the side surface shield electrode 55, in addition to the plurality of electronic components 50 and the outer terminals 5a to 5e which are described above.

The mounting substrate 51 is a substrate on which the plurality of electronic components 50 are disposed (mounted). For example, the mounting substrate 51 has a rectangular flat plate shape in a plan view when viewed in a thickness direction D1 of the mounting substrate 51. For example, the mounting substrate 51 is a resin multilayer substrate. Without being limited to the resin multilayer substrate, for example, the mounting substrate 51 may be a printed wiring board, a low temperature co-fired ceramics (LTCC) substrate, or a high temperature co-fired ceramics (HTCC) substrate.

The mounting substrate 51 has a first main surface 51a, a second main surface 51b, and an outer peripheral surface 51c. The first main surface 51a and the second main surface 51b are main surfaces facing each other in the thickness direction D1 of the mounting substrate 51. The outer peripheral surface 51c is a tubular surface connecting outer peripheral edges of each of the first main surface 51a and the second main surface 51b. The plurality of pad electrodes 52 are provided on the first main surface 51a of the mounting substrate 51. The plurality of pad electrodes 52 are portions where outer electrodes 50a (to be described below) of each of the plurality of electronic components 50 are connected by soldering, for example. The plurality of outer terminals 5a to 5e of the high frequency module 1 are provided on the second main surface 51b of the mounting substrate 51. In FIG. 2, as an example, only the outer terminals 5a and 5e are shown.

More specifically, for example, the mounting substrate 51 is a multilayer substrate including a plurality of dielectric layers (insulating layers) and a plurality of conductive layers. The plurality of dielectric layers and the plurality of conductive layers are alternately laminated in the thickness direction D1 of the mounting substrate 51. The plurality of conductive layers are formed in a predetermined pattern determined for each layer. A material of each conductive layer is copper, for example. The plurality of conductive layers each are electrically connected to other conductive layers, the plurality of pad electrodes 52, or the plurality of outer terminals 5a to 5e by via electrodes provided in the mounting substrate 51.

The plurality of conductive layers include a ground layer 51g. The ground layer 51g is electrically connected to the outer terminal 5e by a via electrode 51e provided in the mounting substrate 51. The outer terminal 5e is a ground terminal electrically connected to the ground. The ground layer 51g is connected to the ground with the outer terminal 5e interposed therebetween to maintain the potential of the ground layer 51g at the ground potential. The ground layer 51g is electrically connected to the pad electrode 52 electrically connected to a ground electrode 50g (to be described below) of each of the plurality of electronic components 50 by a via electrode 51f provided in the mounting substrate 51. The ground layer 51g is electrically connected to the outer shield electrode 54 on the outer peripheral surface 51c of the mounting substrate 51.

For example, the mounting substrate 51 is a substrate having a single-surface mounting structure in which the plurality of electronic components 50 are mounted on one surface (for example, the first main surface 51a) of the mounting substrate 51. The plurality of electronic components 50 are disposed (mounted) on the first main surface 51a of the mounting substrate 51. In the example in FIG. 2, as an example, in the plurality of electronic components 50, only the first electronic component 50A, the second electronic component 50B, and the third electronic component 50C are shown.

More specifically, each of the plurality of electronic components 50 includes the plurality of outer electrodes 50a. Each of the plurality of outer electrodes 50a is connected to any one of the plurality of pad electrodes 52 provided on the first main surface 51a of the mounting substrate 51 by soldering, for example. The plurality of outer electrodes 50a include the ground electrode 50g. The ground electrode 50g is connected to the pad electrode 52 electrically connected to the ground layer 51g by soldering, for example.

For example, the first electronic component 50A is any one of the electronic components 50 for transmission. The electronic component 50 for transmission is the electronic component 50 used in a case that the transmission signal is transmitted in the plurality of electronic components 50, and is the electronic component 50 connected to the first signal path L1 (transmission path). In Embodiment 1, for example, the first electronic component 50A is any of the transmission filter 7, the power amplifier 10, the matching circuit 13, and the matching circuit 14.

For example, the second electronic component 50B is any one of the electronic components 50 for reception. The electronic component 50 for reception is the electronic component 50 used in a case that the reception signal is received in the plurality of electronic components 50, and is the electronic component 50 connected to the second signal path L2 (reception path). In Embodiment 1, for example, the second electronic component 50B is any of the reception filter 8, the low noise amplifier 11, the matching circuit 15, and the matching circuit 16.

The third electronic component 50C is the electronic component 50 disposed between the first electronic component 50A and the second electronic component 50B on the first main surface 51a of the mounting substrate 51. The description of “C is disposed between A and B” in Embodiment 1 means that in a plan view of the mounting substrate 51 when viewed in the thickness direction D1, at least one of a plurality of line segments connecting any point inside a region of A and any point in a region of B passes through a region of C. For example, the third electronic component 50C is the acoustic wave filter (for example, the SAW filter, the BAW filter, or the FBAR filter) having a piezoelectric element, such as the transmission filter 7 or the reception filter 8.

The third electronic component 50C has a top surface 50s and an outer peripheral surface 50t. The top surface 50s is the main surface of the third electronic component 50C on a side opposite to the mounting substrate 51. The outer peripheral surface 50t is a tubular surface extending from an outer peripheral edge of the top surface 50s to the mounting substrate 51 side in the third electronic component 50C. More specifically, the outer peripheral surface 50t has a plurality of (for example, four) side surfaces. That is, the third electronic component 50C has a plate shape of a polygon (for example, a quadrangle) in a plan view in the thickness direction of the third electronic component 50C (thickness direction D1 of the mounting substrate 100).

A height d3 of the third electronic component 50C is higher than a height of the other electronic components 50 (in FIG. 2, a height d2 of the first electronic component 50A and the height d2 of the second electronic component 50B). In this manner, as will be described below, in the plurality of electronic components 50, the top surface 50s of only the third electronic component 50C is brought into direct contact with the outer shield electrode 54. In this manner, the top surface 50s of the third electronic component 50C and the outer shield electrode 54 can be electrically connected. Here, the “height of the electronic component 50” is a distance from the first main surface 51a of the mounting substrate 51 to the top surface of the electronic component 50 in the electronic component 50. Here, the “top surface of the electronic component 50” is the main surface on a side opposite to the side of the mounting substrate 51 side in the electronic component 50.

The side surface shield electrode 55 is provided in at least a portion (for example, side surfaces 50u and 50v) of the outer peripheral surface 50t of the third electronic component 50C. The side surface shield electrode 55 is formed of a conductive member (for example, copper or the like). The side surface shield electrode 55 is disposed between the first electronic component 50A and the second electronic component 50B, and is a member that can shield the electronic components from the electromagnetic waves propagating from the first electronic component 50A which is the electronic component 50 for transmission to the second electronic component 50B which is the electronic component 50 for reception.

More specifically, the side surface shield electrode 55 is provided on at least one side surface of the four side surfaces of the outer peripheral surface 50t of the third electronic component 50C. More specifically, the four side surfaces include a first side surface 50u facing the first electronic component 50A and a second side surface 50v facing the second electronic component 50B. The side surface shield electrode 55 is provided on at least one side surface of the first side surface 50u and the second side surface 50v. In the example in FIG. 2, the side surface shield electrode 55 is provided on the first side surface 50u and the second side surface 50v. In Embodiment 1, for example, the side surface shield electrode 55 is provided on the entire outer peripheral surface 50t of the third electronic component 50C.

The side surface shield electrode 55 includes an end portion 55a. The end portion 55a is an end portion on the top surface 50s side of the third electronic component 50C in the side surface shield electrode 55. The end portion 55a is disposed in an outer peripheral edge of the top surface 50s. The end portion 55a and the outer shield electrode 54 come into contact with each other such that the side surface shield electrode 55 and the outer shield electrode 54 are electrically connected. The side surface shield electrode 55 is electrically connected to the ground layer 51g of the mounting substrate 51 with the outer shield electrode 54 interposed therebetween. In this manner, the potential of the side surface shield electrode 55 is maintained at the ground potential.

The resin member 53 seals the plurality of electronic components 50 disposed on the first main surface 51a of the mounting substrate 51. The resin member 53 includes a resin (for example, an epoxy resin). The resin member 53 may include a filler in addition to the resin. The resin member 53 is provided on the first main surface 51a of the mounting substrate 51. The resin member 53 covers the first main surface 51a of the mounting substrate 51. The resin member 53 covers the plurality of electronic components 50 disposed on the first main surface 51a of the mounting substrate 51. More specifically, the resin member 53 covers the entire electronic component 50 with regard to the electronic component 50 other than the third electronic component 50C. With regard to the third electronic component 50C, the resin member 53 exposes the top surface 50s, and covers surfaces other than the top surface 50s out of the outer surfaces of the third electronic component 50C. The resin member 53 covers the side surface shield electrode 55 provided on the outer peripheral surface 50t of the third electronic component 50C. More specifically, the resin member 53 exposes the end portion 55a, and covers surfaces other than the end portion 55a in the side surface shield electrode 55.

An outer surface 53s of the resin member 53 has a top surface 53q and an outer peripheral surface 53r. The top surface 53q is a main surface on a side opposite to the side of the mounting substrate 51 in the resin member 53. The outer peripheral surface 53r is a surface that extends in a tubular shape from the outer peripheral surface of the top surface 53q to the mounting substrate 51 side. The top surface 53q of the resin member 53 is flat (flush) with the top surface 50s of the third electronic component 50C.

The outer shield electrode 54 is a member for shielding the inside and the outside of the high frequency module 1 in an electromagnetic manner. The outer shield electrode 54 is formed of a conductive member (for example, copper). For example, the outer shield electrode 54 is formed of one metal layer. Without being limited thereto, the outer shield electrode 54 may be a multilayer structure in which a plurality of metal layers are laminated. The outer shield electrode 54 is provided on at least the outer surface 53s of the resin member 53, and covers the entire outer surface 102s of the resin member 53.

More specifically, the outer shield electrode 54 covers the entire outer surface 53s of the resin member 53, the top surface 50s of the third electronic component 50C, the end portion 55a of the side surface shield electrode 55, and at least a portion of the outer peripheral surface 51c of the mounting substrate 51. The outer shield electrode 54 covers at least a portion of the outer peripheral surface 51c of the mounting substrate 51 to be electrically connected to the ground layer 51g of the mounting substrate 51 on the outer peripheral surface 51c of the mounting substrate 51. In this manner, the potential of the outer shield electrode 54 is maintained at the ground potential with the ground layer 51g interposed therebetween. In addition, the outer shield electrode 54 covers the top surface 50s of the third electronic component 50C and the end portion 55a of the side surface shield electrode 55. The outer shield electrode 54 covers the end portion 55a of the side surface shield electrode 55 to be electrically connected to the end portion 55a of the side surface shield electrode 55. In this manner, the side surface shield electrode 55 is maintained at the ground potential with the outer shield electrode 54 interposed therebetween.

### (6) Example of Structure of Third Electronic Component

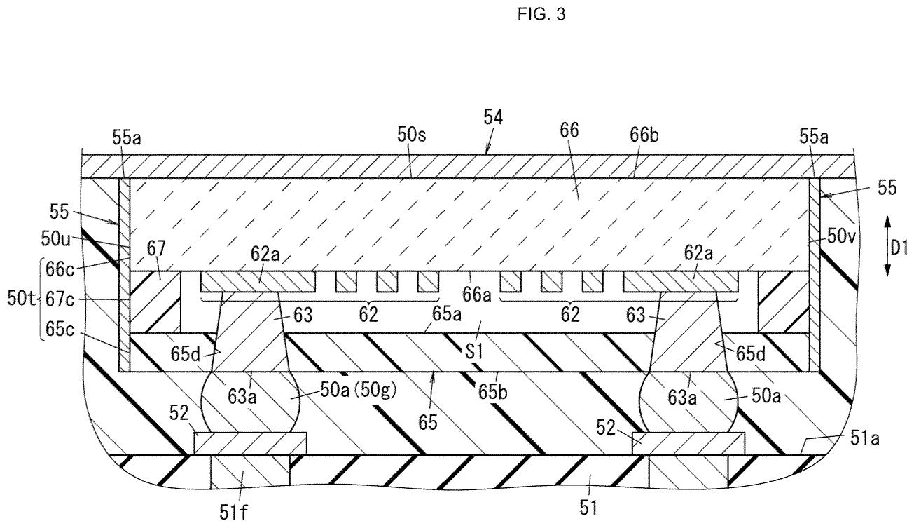

As shown in FIG. 3, for example, the third electronic component 50C is the acoustic wave filter. The third electronic component 50C includes a piezoelectric substrate 66, a plurality of IDT electrodes 62, a plurality of terminals 63, a spacer layer 67, a cover member 65, and a plurality of outer electrodes 50a.

The piezoelectric substrate 66 has a first main surface 66a and a second main surface 66b which face each other.

The IDT electrode 62 is provided on the first main surface 66a of the piezoelectric substrate 66. The first main surface 66a is the main surface facing the first main surface 51a of the mounting substrate 51 in the piezoelectric substrate 66. For example, a material of the piezoelectric substrate 66 is lithium tantalate or lithium niobate. The IDT electrode 62 includes an extended electrode 62a.

The plurality of terminals 63 are electrically connected to the extended electrode 62a determined in the extended electrodes 62a of each of the plurality of IDT electrodes 62. For example, the plurality of terminals 63 have a columnar shape. The plurality of terminals 63 are disposed in an erected state on the first main surface 66a of the piezoelectric substrate 66. The plurality of terminals 63 are provided to penetrate the cover member 65 (to be described below). An end surface 63a of each of the plurality of terminals 63 is exposed from a second main surface 65b (main surface in an outer side portion) of the cover member 65 (to be described below).

The spacer layer 67 is provided in a frame shape to surround the plurality of IDT electrodes 62 on the first main surface 66a of the piezoelectric substrate 66. In the shown example in FIG. 3, the spacer layer 67 is provided along a peripheral edge portion of the first main surface 66a of the piezoelectric substrate 66. The spacer layer 67 is formed of an electric insulating member. More specifically, for example, the spacer layer 67 is formed of an epoxy resin, polyimide, or the like.

The cover member 65 is disposed on the spacer layer 67 to cover the plurality of IDT electrodes 62 at an interval. The cover member 65 has a flat plate shape having the same outer shape size as an outer shape size of the piezoelectric substrate 66 in a plan view in the thickness direction (that is, the thickness direction D1 of the mounting substrate 100) of the third electronic component 50C. The cover member 65 is formed of an electric insulating member. More specifically, for example, the cover member 65 is formed of an epoxy resin, polyimide, or the like.

The cover member 65 has a first main surface 65a and a second main surface 65b which face each other in the thickness direction (that is, the thickness direction D1 of the mounting substrate 51) of the cover member 65. The first main surface 65a is the main surface facing the piezoelectric substrate 66. The second main surface 65b is the main surface facing the mounting substrate 51. The cover member 65 includes a plurality of through holes 65d that penetrate the cover member 65 in the thickness direction. An end portion of the corresponding terminal 63 is inserted into the plurality of through holes 65d. The end surface 63a of each of the plurality of terminals 63 is exposed and disposed on the second main surface 65b of the cover member 65.

The third electronic component 50C has an accommodation space S1 that accommodates the plurality of IDT electrodes 62. The accommodation space S1 is surrounded by the piezoelectric substrate 66, the spacer layer 67, and the cover member 65. A gas is contained in the accommodation space S1. The gas is air, an inert gas (for example, a nitrogen gas), or the like.

The plurality of outer electrodes 50a are portions electrically connected to the pad electrodes 52 of the mounting substrate 51. The plurality of outer electrodes 50a correspond one-to-one to the plurality of terminals 63, and are provided on the end surfaces 63a of the corresponding terminals 63.

As described above, the third electronic component 50C has the top surface 50s and the outer peripheral surface 50t. The top surface 50s is formed by the second main surface 66b of the piezoelectric substrate 66. The outer peripheral surface 50t includes an outer peripheral surface 66c of the piezoelectric substrate 66, an outer peripheral surface 67c of the spacer layer 67, and an outer peripheral surface 65c of the cover member 65. In a plan view in the thickness direction of the third electronic component 50C (that is, the thickness direction D1), the shape of the third electronic component 50C is a polygon (for example, a quadrangle). Therefore, the outer peripheral surface 50t has a plurality of (for example, four) side surfaces. The plurality of side surfaces include a first side surface 50u facing the first electronic component 50A and a second side surface 50v facing the second electronic component 50B.

As described above, the side surface shield electrode 55 is provided in at least a portion of the outer peripheral surface 50t of the third electronic component 50C. In the shown example in FIG. 3, the side surface shield electrode 55 is provided on the first side surface 50u and the second side surface 50v of the third electronic component 50C.

### (7) Disposition of Plurality of Electronic Components

As shown in FIG. 2, the first main surface 51a of the mounting substrate 51 has a first region R1, a second region R2, and a third region R3.

In the first region R1, the electronic components 50 for transmission other than the transmission filter 7 in the plurality of electronic components 50 are collected and disposed. In the example in FIG. 2, in the first region R1, only the first electronic component 50A is shown as an example of the electronic component 50 for transmission other than the transmission filter 7.

The second region R2 is a region separated from the first region R1. In the second region R2, the electronic components 50 for reception other than the reception filter 8 in the plurality of electronic components 50 are collected and disposed. In the shown example in FIG. 2, in the second region R2, only the second electronic component 50B is shown as an example of the electronic component 50 for reception other than the reception filter 8.

The third region R3 is a region between the first region R1 and the second region R2. For example, the third region R3 is a central region of the first main surface 51a of the mounting substrate 51. In the third region R3, the acoustic wave filters (for example, the transmission filter 7 and the reception filter 8) in the plurality of electronic components 50 are collected and disposed. In the shown example in FIG. 3, in the third region R3, only the third electronic component 50C is shown as an example of the acoustic wave filter.

In this way, in the plurality of electronic components 50, the electronic components 50 for transmission other than the transmission filter 7 are collected and disposed in the first region R1, and the electronic components 50 for reception other than the reception filter 8 are collected and disposed in the second region R2. The acoustic wave filters such as the transmission filter 7 and the reception filter 8 are collected and disposed in the third region R3 between the first region R1 and the second region R2.

In Embodiment 1, the side surface shield electrode 55 is provided on the outer peripheral surface 50t of the third electronic component 50C disposed in the third region R3 by using the disposition of the plurality of electronic components 50 configured in this way. In this way, the side surface shield electrode 55 is disposed by using the outer peripheral surface 50t of the third electronic component 50C disposed in the third region. In this manner, it is not necessary to secure a disposition space for disposing the side surface shield electrode 55 on the first main surface 51a of the mounting substrate 51. Therefore, the high frequency module 1 can achieve size reduction even in a case that the side surface shield electrode 55 is disposed on the mounting substrate 51.

### (8) Shielding Characteristics of Side Surface Shield Electrode

As shown in FIG. 2, the side surface shield electrode 55 is provided in at least a portion of the outer peripheral surface 50t of the third electronic component 50C disposed between the first electronic component 50A and the second electronic component 50B. In this manner, electromagnetic waves (signals) that reach the second electronic component 50B side from the first electronic component 50A are reflected by the side surface shield electrode 55. In this manner, the electromagnetic waves that reach the second electronic component 50B from the first electronic component 50A are reduced at a time of being transmitted to the second electronic component 50B. That is, interference of the electromagnetic waves (signals) between the first electronic component 50A and the second electronic component 50B is reduced by the side surface shield electrode 55.

### (9) Manufacturing Method for High Frequency Module

An example of a manufacturing method for the high frequency module 1 will be described with reference to FIG. 2. First, the side surface shield electrode 55 is provided on the outer peripheral surface 50t of the third electronic component 50C by sputtering, for example. The plurality of electronic components 50 are disposed (mounted) on the first main surface 51a of the mounting substrate 51. In this manner, the first electronic component 50A, the second electronic component 50B, and the third electronic component 50C provided with the side surface shield electrode 55 are disposed (mounted) on the first main surface 51a of the mounting substrate 51. In this disposition state, the outer electrodes 50a of each of the plurality of electronic components 50 are connected to the pad electrode 52 determined in advance in the plurality of pad electrodes 52 disposed on the first main surface 51a of the mounting substrate 51 by soldering.

The resin member 53 is provided on the first main surface 51a of the mounting substrate 51 to cover the top surface of each of the plurality of electronic components 50. The top surface of the resin member 53 is cut by a cutting device until the top surface 50s of the third electronic component 50C and the end portion 55a of the side surface shield electrode 55 are exposed. In this cut state, the end portion 55a of the side surface shield electrode 55 is disposed in the outer peripheral edge of the top surface 50s of the third electronic component 50C. The end portion 55a of the side surface shield electrode 55 is exposed from the resin member 53 together with the top surface 50s.

For example, the outer shield electrode 54 is provided by sputtering to cover the outer surface 53s (top surface and outer peripheral surface) of the resin member 53, the top surface 50s of the third electronic component 50C, the end portion 55a of the side surface shield electrode 55, and the outer peripheral surface 51c of the mounting substrate 51. In a state where the outer shield electrode 54 is provided in this way, the end portion 55a of the side surface shield electrode 55 is directly connected to the outer shield electrode 54. In addition, the ground layer 51g of the mounting substrate 51 is directly connected to the outer shield electrode 54 on the outer peripheral surface 51c of the mounting substrate 51. In this way, the side surface shield electrode 55 is electrically connected to the ground layer 51g with the outer shield electrode 54 interposed therebetween. In this way, the high frequency module 1 is manufactured.

### (10) Advantageous Effects

The high frequency module 1 according to Embodiment 1 includes the mounting substrate 51, the first electronic component 50A, the second electronic component 50B, the third electronic component 50C, and the side surface shield electrode 55. The mounting substrate 51 has a first main surface 51a and a second main surface 51b which face each other. The first electronic component 50A is disposed on the first main surface 51a of the mounting substrate 51. The second electronic component 50B is disposed on the first main surface 51a of the mounting substrate 51. The third electronic component 50C is disposed between the first electronic component 50A and the second electronic component 50B on the first main surface 51a of the mounting substrate 51. The side surface shield electrode 55 is provided in at least a portion of the outer peripheral surface 50t of the third electronic component 50C. The mounting substrate 51 includes a ground layer 51g. The side surface shield electrode 55 is connected to the ground layer 51g.

According to this configuration, interference of electromagnetic waves (signals) between the first electronic component 50A and the second electronic component 50B can be reduced by the side surface shield electrode 55 provided on an outer peripheral surface 50t of the third electronic component 50C. In addition, the side surface shield electrode 55 is disposed by using the outer peripheral surface 50t of the third electronic component 50C. Therefore, it is not necessary to secure a disposition space for disposing a shield wall on the first main surface 51a of the mounting substrate 51, compared to a case that the shield wall is disposed separately from the third electronic component 50C. As a result, the high frequency module 1 can achieve size reduction.

In addition, the high frequency module 1 according to Embodiment 1 further includes the resin member 53 and the outer shield electrode 54. The resin member 53 is provided on the first main surface 51a of the mounting substrate 51 to cover the first electronic component 50A, the second electronic component 50B, the third electronic component 50C, and the side surface shield electrode 55. The outer shield electrode 54 is provided on at least the outer surface 53s of the resin member 53, and is connected to the ground layer 51g. The side surface shield electrode 55 is connected to the outer shield electrode 54. According to this configuration, the side surface shield electrode 55 can be connected to the ground layer 51g of the mounting substrate 51 with a simple structure by using the outer shield electrode 54.

In addition, in the high frequency module 1 according to Embodiment 1, the third electronic component 50C is the acoustic wave filter (transmission filter 7 or reception filter 8) including the piezoelectric substrate. According to this configuration, since the acoustic wave filter is used for transmission and reception, in many cases, the acoustic wave filter is disposed between a transmission area (first region R1) and a reception area (second region R2). Since the side surface shield electrode 55 is provided on the outer peripheral surface of the acoustic wave filter, isolation between the transmission area and the reception area can be improved without significantly changing the disposition of the electronic component 50 to be disposed on the mounting substrate 51.

In addition, the communication device 30 according to Embodiment 1 includes the high frequency module 1 and the signal processing circuit 2. The signal processing circuit 2 is connected to the high frequency module 1 to perform signal processing on the high frequency signal. According to this configuration, the communication device 30 achieving the advantageous effects of the high frequency module 1 can be provided.

### (11) Modification Example

Modification examples of Embodiment 1 will be described. The modification examples described below can be implemented in combination.

### (11-1) Modification Example 1

In Embodiment 1, the electronic component 50 for transmission, the electronic component 50 for reception, and the acoustic wave filters (transmission filter 7 and reception filter 8) each are disposed by being divided into the first region R1, the second region R2, and the third region R3 of the mounting substrate 51, but may be disposed without being divided. In this case, the electronic component 50 disposed between the two electronic components 50 (first electronic component and second electronic component) which need to be electromagnetically shielded is set as the third electronic component 50C, and the side surface shield electrode 55 is provided in at least a portion of the outer peripheral surface of the third electronic component 50C. In this case, without being limited to the acoustic wave filter, the third electronic component 50C may be an IC chip such as the switch, the low noise amplifier, and the power amplifier, a multilayer LC filter which is a surface mount device (SMD) component, or the like.

### (11-2) Modification Example 2

In Embodiment 1, a single-surface mounting structure in which the plurality of electronic components 50 are disposed only on the first main surface 51a of the mounting substrate 51 is adopted. However, in Embodiment 1, a double-surface mounting structure in which the plurality of electronic components 50 are disposed in a dispersed manner on both the first main surface 51a and the second main surface 51b of the mounting substrate 51 may be adopted.

### Embodiment 2

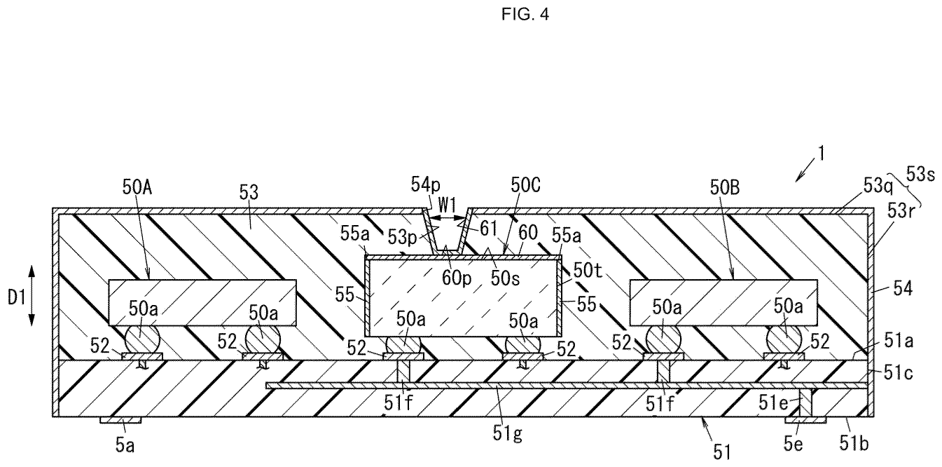

The high frequency module 1 according to Embodiment 2 will be described with reference to FIG. 4. In the following description, the same reference numerals as those in Embodiment 1 will be assigned to the same components as those in Embodiment 1, and description thereof will be omitted. In some cases, only the components different from those in Embodiment 1 will be described.

### (1) Configuration

As shown in FIG. 4, in the high frequency module 1 according to Embodiment 2, the high frequency module 1 according to Embodiment 1 further includes a top surface shield electrode 60 and a connection member 61. The top surface shield electrode 60 is provided in at least a portion of the top surface 50s of the third electronic component 50C. In the example in FIG. 4, the top surface shield electrode 60 is provided on the entire top surface 50s of the third electronic component 50C. The top surface shield electrode 60 is formed of a conductive member (for example, copper or the like). The top surface shield electrode 60 is electrically connected to the side surface shield electrode 55 provided on the outer peripheral surface 50t of the third electronic component 50C. In the example in FIG. 4, the top surface shield electrode 60 is electrically connected to the side surface shield electrode 55 by being connected to (coming into contact with) the end portion 55a of the side surface shield electrode 55.

The resin member 53 of Embodiment 2 further covers the top surface shield electrode 60 provided in the third electronic component 50C in the resin member 53 of Embodiment 1. The resin member 53 includes a through hole 53p. The through hole 53p is provided in the resin member 53 to penetrate between the top surface 53q of the resin member 53 and the top surface shield electrode 60. In this manner, the through hole 53p exposes a portion 60p of the top surface shield electrode 60 from the top surface 53q of the resin member 53. Here, the top surface 53q is the main surface on a side opposite to the side of the mounting substrate 51 in the resin member 53. The through hole 53p is provided in the resin member 53 to penetrate between the top surface 53q of the resin member 53 and the top surface shield electrode 60.

In the example in FIG. 4, a width W1 of the through hole 53p decreases toward the top surface shield electrode 60 side from the top surface 53q side of the resin member 53, but may be constant toward the top surface shield electrode 60 side from the top surface 53q of the resin member 53.

In the outer shield electrode 54 of Embodiment 1, the outer shield electrode 54 of Embodiment 2 is provided on the outer surface 53s (top surface 53q and outer peripheral surface 53r) of the resin member 53 and the outer peripheral surface 51c of the mounting substrate 51 to expose the through hole 53p. The outer shield electrode 54 has a cavity 54p connected to the through hole 53p. As in the case of Embodiment 1, the outer shield electrode 54 is electrically connected to the ground layer 51g of the mounting substrate 51.

The connection member 61 is a member that electrically connects the outer shield electrode 54 and the top surface shield electrode 60. The connection member 61 is formed of a conductive member (for example, copper or the like). The connection member 61 is formed of the same member as that of the outer shield electrode 54. The connection member 61 is provided in a layer shape to cover the inner peripheral surface of the cavity 54p of the outer shield electrode 54, the inner peripheral surface of the through hole 53p, and the portion 60p of the top surface shield electrode 60. That is, for example, the connection member 61 is a recessed conductor layer. The connection member 61 electrically connects the outer shield electrode 54 and the top surface shield electrode 60.

The side surface shield electrode 55 of Embodiment 2 is electrically connected to the outer shield electrode 54 with the connection member 61 interposed therebetween. In this manner, in Embodiment 2, the side surface shield electrode 55 and the outer shield electrode 54 can be electrically connected by the connection member 61, even in a case that the top surface 53q of the resin member 53 and the top surface 50s of the third electronic component 50C are not flat (flush) with each other.

The side surface shield electrode 55 of Embodiment 2 is electrically connected to the ground layer 51g of the mounting substrate 51 with the top surface shield electrode 60, the connection member 61, and the outer shield electrode 54 interposed therebetween. In this manner, as in the side surface shield electrode 55 of Embodiment 1, the interference of the electromagnetic waves (signals) between the first electronic component 50A and the second electronic component 50B can be reduced.

### (2) Manufacturing Method for High Frequency Module

An example of a manufacturing method for the high frequency module 1 according to Embodiment 2 will be described with reference to FIG. 4. First, the side surface shield electrode 55 and the top surface shield electrode 60 each are provided on the outer peripheral surface 50t and the top surface 50s of the third electronic component 50C by sputtering, for example. In this state, the top surface shield electrode 60 is electrically connected to the end portion 55a of the side surface shield electrode 55. The side surface shield electrode 55 and the top surface shield electrode 60 are provided together in one manufacturing step to be integrally formed of the same material.

The plurality of electronic components 50 are disposed (mounted) on the first main surface 51a of the mounting substrate 51. In this manner, the first electronic component 50A, the second electronic component 50B, and the third electronic component 50C provided with the side surface shield electrode 55 and the top surface shield electrode 60 are disposed (mounted) on the first main surface 51a of the mounting substrate 51. In this disposition state, the outer electrodes 50a of each of the plurality of electronic components 50 are connected to the pad electrode 52 determined in advance in the plurality of pad electrodes 52 disposed on the first main surface 51a of the mounting substrate 51 by soldering.

The resin member 53 is provided on the first main surface 51a of the mounting substrate 51 to cover the top surface of each of the plurality of electronic components 50. The through hole 53p is provided in the resin member 53 by laser beams. The through hole 53p exposes the portion 60p of the top surface shield electrode 60 from the top surface 53q of the resin member 53.

The outer shield electrode 54 is provided to cover the outer surface 53s (top surface 53q and outer peripheral surface 53r) of the resin member 53 and the outer peripheral surface 51c of the mounting substrate 51 by sputtering, for example. In addition, the connection member 61 is provided to cover the cavity 54p of the outer shield electrode 54, the inner peripheral surface of the through hole 53p, and the portion 60p of the top surface shield electrode 60 by sputtering, for example. The outer shield electrode 54 and the connection member 61 are provided together in one step to be integrally formed of the same material.

In this way, in a state where the outer shield electrode 54 and the connection member 61 are provided, the side surface shield electrode 55 is electrically connected to the outer shield electrode 54 with the top surface shield electrode 60 and the connection member 61 interposed therebetween. The side surface shield electrode 55 is electrically connected to the ground layer 51g of the mounting substrate 51 with the top surface shield electrode 60, the connection member 61, and the outer shield electrode 54 interposed therebetween. In this way, the high frequency module 1 is manufactured.

### (3) Advantageous Effects

The high frequency module 1 according to Embodiment 2 includes the top surface shield electrode 60 and the connection member 61. The top surface shield electrode 60 is provided on the main surface 50s on a side opposite to the side of the mounting substrate 51 in the third electronic component 50C, and is connected to the side surface shield electrode 55. The connection member 61 connects the top surface shield electrode 60 and the outer shield electrode 54. According to this configuration, the side surface shield electrode 55 and the outer shield electrode 54 can be connected by the connection member 61 without exposing the entire top surface 50s of the third electronic component 50C from the resin member 53.

### (4) Modification Examples

Modification examples of Embodiment 2 will be described. The following modification examples can be implemented in combination with each other. In addition, the following modification examples can be implemented in combination with Embodiment 1 and the modification examples thereof.

### (4-1) Modification Example 1

In Embodiment 2, a case where the connection member 61 is the recessed conductor layer has been described as an example. However, without being limited to the recessed conductor layer, the connection member 61 may be a filling conductor that fills the inside of the through hole 53p. In a case that the connection member 61 is the filling conductor, the connection member 61 and the outer shield electrode 54 are flat (flush) with each other.

### (4-2) Modification Example 2

In Embodiment 2, the connection member 61 is integrally formed of the same material as that of the outer shield electrode 54, but may be formed of mutually separate bodies.

### (4-3) Modification Example 3

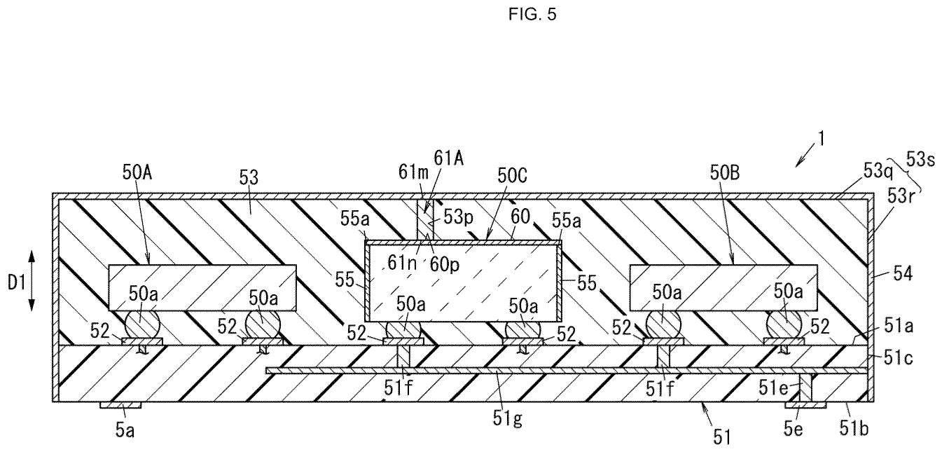

In Embodiment 2, the connection member 61 is provided in a recessed layer shape (refer to FIG. 4), but as shown in FIG. 5, in Modification Example 3, a connection member 61A includes a metal pin terminal.

The through hole 53p of the resin member 53 of Modification Example 3 is a tubular shape, for example. As in the case of Embodiment 2, the through hole 53p penetrates between the top surface 53q of the resin member 53 and the top surface shield electrode 60, and exposes the portion 60p of the top surface shield electrode 60 from the top surface 53q of the resin member 53.

The connection member 61A of Modification Example 3 is the metal pin terminal that electrically connects the outer shield electrode 54 and the top surface shield electrode 60. The connection member 61A has a columnar shape having the same shape and the same size as the through hole 53p. A first end portion 61m which is one end portion of the connection member 61A is electrically connected to a back surface of the outer shield electrode 54, and a second end portion 61n which is the other end portion of the connection member 61A is electrically connected to the portion 60p of the top surface shield electrode 60.

The outer shield electrode 54 of Modification Example 3 covers the outer surface 53s of the resin member 53, the first end portion 61m of the connection member 61A, and the outer peripheral surface 51c of the mounting substrate 51. The outer shield electrode 54 covers the first end portion 61m of the connection member 61A to be electrically connected to the first end portion 61m of the connection member 61A. The outer shield electrode 54 covers the outer peripheral surface 51c of the mounting substrate 51 to be electrically connected to the end portion of the ground layer 51g of the mounting substrate 51.

In Modification Example 3, the side surface shield electrode 55 is electrically connected to the ground layer 51g of the mounting substrate 51 with the top surface shield electrode 60, the connection member 61A, and the outer shield electrode 54 interposed therebetween. In this manner, as in Embodiment 1, the interference of the electromagnetic waves (signals) between the first electronic component 50A and the second electronic component 50B can be reduced by the side surface shield electrode 55.

An example of a manufacturing method for the high frequency module 1 according to Modification Example 3 will be described with reference to FIG. 5.

First, as in the case of Embodiment 2, the side surface shield electrode 55 and the top surface shield electrode 60 each are provided on the outer peripheral surface 50t and the top surface 50s of the third electronic component 50C by sputtering, for example.

The plurality of electronic components 50 are disposed (mounted) on the first main surface 51a of the mounting substrate 51. In this manner, the first electronic component 50A, the second electronic component 50B, and the third electronic component 50C provided with the side surface shield electrode 55 and the top surface shield electrode 60 are disposed (mounted) on the first main surface 51a of the mounting substrate 51. In this disposition state, the outer electrodes 50a of each of the plurality of electronic components 50 are connected to the pad electrode 52 determined in advance in the plurality of pad electrodes 52 disposed on the first main surface 51a of the mounting substrate 51 by soldering.

The second end portion 61n of the connection member 61A and the portion 60p of the top surface shield electrode 60 are connected by soldering, for example. In this manner, the connection member 61A is provided in an erected state in the portion 60p of the top surface shield electrode 60.

The resin member 53 is provided on the first main surface 51a of the mounting substrate 51 to cover the top surface of each of the plurality of electronic components 50. In this case, the resin member 53 is provided to cover the outer peripheral surface of the connection member 61A and to expose the first end portion 61m of the connection member 61A. In this state, the first end portion 61m of the connection member 61A and the top surface 53q of the resin member 53 are flat (that is, flush) with each other. In a case that the first end portion 61m of the connection member 61A protrudes from the top surface 53q of the resin member 53, the first end portion 61m of the connection member 61A is cut such that the first end portion 61m of the connection member 61A and the top surface 53q of the resin member 53 are flat.

The outer shield electrode 54 is provided to cover the outer surface 53s (top surface 53q and outer peripheral surface 53r) of the resin member 53, the first end portion 61m of the connection member 61A, and the outer peripheral surface 51c of the mounting substrate 51 by sputtering, for example. In this way, the high frequency module 1 is manufactured.

According to Modification Example 1, the connection member 61A can be formed of the metal pin terminal (that is, a simple configuration).

The connection member 61A is provided to be directly connected to the top surface shield electrode 60, but may be provided to be directly connected to the side surface shield electrode 55. In this case, the top surface shield electrode 60 may be omitted.

### (4-4) Modification Example 4

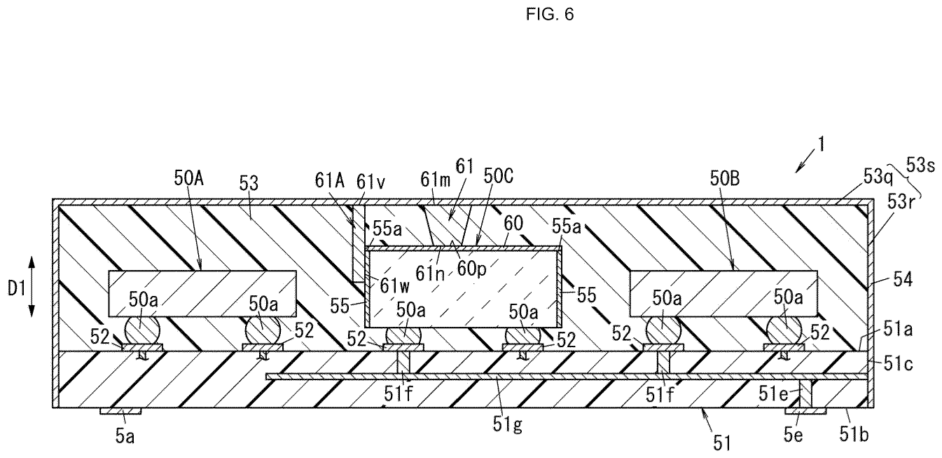

As shown in FIG. 6, Modification Example 4 is a combination of Embodiment 2 and Modification Example 3 of Embodiment 2. More specifically, for example, the high frequency module 1 according to Modification Example 4 includes the connection member 61 which is the filling member, and the connection member 61A which is the metal pin terminal.

The connection member 61 is provided to electrically connect the portion 60p of the top surface shield electrode 60 and the back surface of the outer shield electrode 54. The first end portion 61m of the connection member 61 is connected to the back surface of the outer shield electrode 54, and the second end portion 60n of the connection member 61 is connected to the portion 60p of the top surface shield electrode 60.

The connection member 61A is provided to electrically connect the side surface shield electrode 55 and the outer shield electrode 54. An end portion 61v of the connection member 61A is connected to the back surface of the outer shield electrode 54, and a portion 61w of the outer peripheral surface of the connection member 61A is connected to the side surface shield electrode 55. The end portion 61v of the connection member 61A and the top surface 53q of the resin member 53 are flat (flush) with each other.

As in the case of Embodiment 2, the resin member 53 of Modification Example 4 is provided on the first main surface 51a of the mounting substrate 51 to cover the plurality of electronic components 50. The resin member 53 is provided to cover the outer peripheral surface of the connection member 61 and to expose the first end portion 61m of the connection member 61. In addition, the resin member 53 is provided to expose the end portion 61v of the connection member 61A and to cover the outer surface of the connection member 61A.

The outer shield electrode 54 of Modification Example 4 is provided to cover the top surface 53q and the outer peripheral surface 53r of the resin member 53, the first end portion 61m of the connection member 61, the end portion 61v of the connection member 61A, and the outer peripheral surface 51c of the mounting substrate 51.

In Modification Example 4, the side surface shield electrode 55 is connected to the outer shield electrode 54 with the connection member 61A interposed therebetween, and with the top surface shield electrode 60 and the connection member 61 interposed therebetween. Furthermore, the side surface shield electrode 55 is electrically connected to the ground layer 51g of the mounting substrate 51 with the outer shield electrode 54 interposed therebetween.

According to Modification Example 4, both the advantageous effects of Embodiment 2 and Modification Example 1 are achieved.

### Embodiment 3

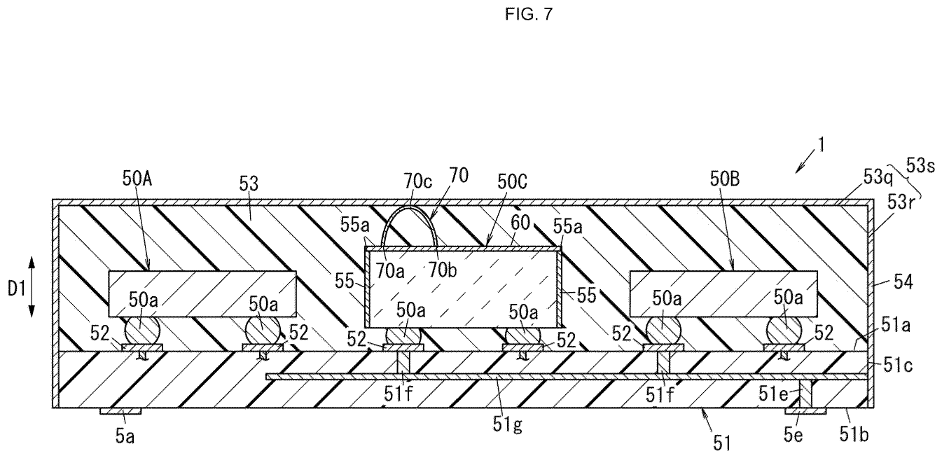

The high frequency module 1 according to Embodiment 3 will be described with reference to FIG. 7. In the following description, the same reference numerals as those in Embodiment 2 will be assigned to the same components as those in Embodiment 2, and description thereof will be omitted. In some cases, only the components different from those in Embodiment 2 will be described.

### (1) Configuration

As shown in FIG. 7, the high frequency module 1 according to Embodiment 3 includes a bonding wire 70 instead of the connection member 61 in the high frequency module 1 according to Embodiment 2.

The bonding wire 70 includes a first end portion 70a, a second end portion 70b, and a predetermined portion 70c. The first end portion 70a is one end portion of the bonding wire 70. The second end portion 70b is the other end portion of the bonding wire 70, and is the end portion different from the first end portion 70a. For example, the predetermined portion 70c is a portion (intermediate portion) between the first end portion 70a and the second end portion 70b in the bonding wire 70.

The first end portion 70a of the bonding wire 70 is electrically connected to the top surface shield electrode 60, and the predetermined portion 70c of the bonding wire 70 is electrically connected to the outer shield electrode 54. More specifically, the bonding wire 70 is bent in a U-shape. The first end portion 70a and the second end portion 70b of the bonding wire 70 are electrically connected to the top surface shield electrode 60. The predetermined portion 70c of the bonding wire 70 is a bent portion bent in a U-shape. The predetermined portion 70c of the bonding wire 70 is electrically connected to the outer shield electrode 54.

The resin member 53 according to Embodiment 3 is provided on the first main surface 51a of the mounting substrate 51 to cover the plurality of electronic components 50. The resin member 53 covers the side surface shield electrode 55 and the top surface shield electrode 60 which are provided in the third electronic component 50C. The resin member 53 exposes the predetermined portion 70c of the bonding wire 70, and covers a portion other than the predetermined portion 70c.

The outer shield electrode 54 of Embodiment 3 is provided to cover the outer surface 53s of the resin member 53, the predetermined portion 70c of the bonding wire 70, and the outer peripheral surface 51c of the mounting substrate 51. The outer shield electrode 54 covers (that is, comes into contact with) the predetermined portion 70c of the bonding wire 70 to be electrically connected to the predetermined portion 70c of the bonding wire 70.

In Embodiment 3, the side surface shield electrode 55 is electrically connected to the ground layer 51g of the mounting substrate 51 with the top surface shield electrode 60, the bonding wire 70, and the outer shield electrode 54 interposed therebetween. In this manner, as in Embodiment 1, the interference of the electromagnetic waves (signals) between the first electronic component 50A and the second electronic component 50B can be reduced by the side surface shield electrode 55.

### (2) Manufacturing Method

Next, an example of a manufacturing method for the high frequency module 1 according to Embodiment 3 will be described with reference to FIG. 7.

First, the plurality of electronic components 50 are disposed (mounted) on the first main surface 51a of the mounting substrate 51. In this manner, the first electronic component 50A, the second electronic component 50B, and the third electronic component 50C provided with the side surface shield electrode 55 and the top surface shield electrode 60 are disposed (mounted) on the first main surface 51a of the mounting substrate 51. In this disposition state, the outer electrodes 50a of each of the plurality of electronic components 50 are connected to the pad electrode 52 determined in advance in the plurality of pad electrodes 52 disposed on the first main surface 51a of the mounting substrate 51 by soldering.

The first end portion 70a and the second end portion 70b of the bonding wire 70 are connected to the top surface shield electrode 60 by soldering, for example. In this connection state, the bonding wire 70 is erected in an inverted U-shape on the top surface shield electrode 60. The bonding wire 70 may be directly bonded to the top surface shield electrode 60 of the third electronic component 50C.

The resin member 53 is provided on the first main surface 51a of the mounting substrate 51 to cover the top surface of each of the plurality of electronic components 50. In this case, the resin member 53 is provided to expose the predetermined portion 70c of the bonding wire 70 and to cover the portion other than the predetermined portion 70c. More specifically, after the resin member 53 is provided to cover the entire bonding wire 70, the top surface side of the resin member 53 is cut by a cutting device until the predetermined portion 70c of the bonding wire 70 is exposed.

The outer shield electrode 54 is provided to cover the outer surface 53s (top surface 53q and outer peripheral surface 53r) of the resin member 53, the predetermined portion 70c of the bonding wire 70, and the outer peripheral surface 51c of the mounting substrate 51 by sputtering, for example. In this way, the high frequency module 1 is manufactured.

### (3) Advantageous Effects

The high frequency module 1 according to Embodiment 3 includes the top surface shield electrode 60 and the bonding wire 70. The top surface shield electrode 60 is provided on the main surface 50s on a side opposite to the side of the mounting substrate 51 in the third electronic component 50C, and is connected to the side surface shield electrode 55. The bonding wire 70 includes the first end portion 70a and the predetermined portion 70c. The predetermined portion 70c is a portion different from the first end portion 70a. The first end portion 70a of the bonding wire 70 is connected to the top surface shield electrode 60, and the predetermined portion 70c of the bonding wire 70 is connected to the outer shield electrode 54.

According to this configuration, the side surface shield electrode 55 and the outer shield electrode 54 can be electrically connected by the bonding wire 70 without exposing the entire top surface 50s of the third electronic component 50C from the resin member 53.

### (4) Modification Examples

Modification examples of Embodiment 3 will be described.

### (4-1) Modification Example 1

In Embodiment 3, the bonding wire 70 may be electrically connected to the outer shield electrode 54 in a divided state in the predetermined portion 70c. In this case, for example, the bonding wire 70 is formed of a pair of (two) divided bonding wires (divided wires). In this case, the divided end portions of each of the pair of divided wires are electrically connected to the outer shield electrode 54 in a state of being adjacent to each other in the outer shield electrode 54. The divided end portion is an end portion at a divided location. One divided wire has the first end portion 70a and a divided end portion, and the other divided wire has the second end portion 70b and a divided end portion. In a plan view in the thickness direction D1 of the mounting substrate 51, an interval between the divided end portion of one divided wire and the divided end portion of the other divided wire is shorter than an interval between the first end portion 70a and the second end portion 70b.

### Embodiment 4

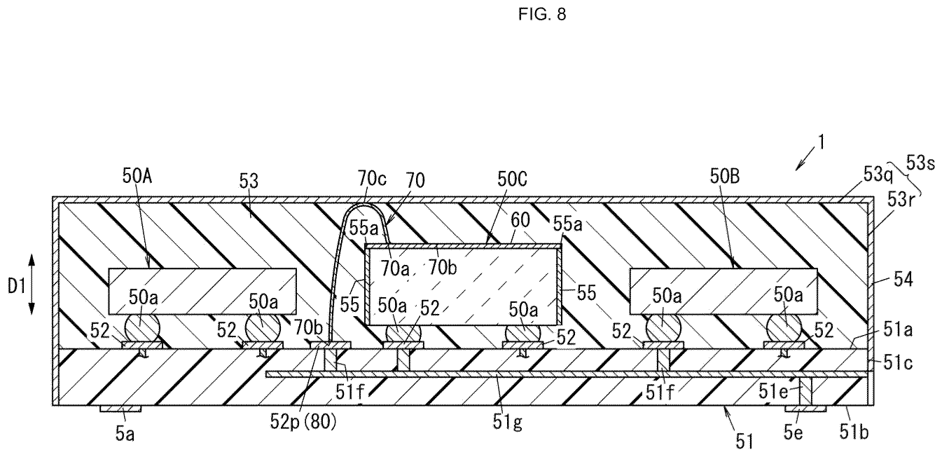

The high frequency module 1 according to Embodiment 4 will be described with reference to FIG. 8. In the following description, the same reference numerals as those in Embodiment 3 will be assigned to the same components as those in Embodiment 3, and description thereof will be omitted. In some cases, only the components different from those in Embodiment 3 will be described.

### (1) Configuration

As shown in FIG. 8, the high frequency module 1 according to Embodiment 4 is configured in the same manner as the high frequency module 1 according to Embodiment 3, except that the second end portion 70b of the bonding wire 70 is electrically connected to the conductive member 80 provided on the first main surface 51a of the mounting substrate 51.

The conductive member 80 is formed of a conductive member. The conductive member 80 is electrically connected to the ground layer 51g of the mounting substrate 51. For example, the conductive member 80 is a pad electrode 52p. The pad electrode 52p is provided on the first main surface 51a of the mounting substrate 51, and is electrically connected to the ground layer 51g of the mounting substrate 51.

In Embodiment 4, the first end portion 70a of the bonding wire 70 is electrically connected to the top surface shield electrode 60. The second end portion 70b of the bonding wire 70 is electrically connected to the conductive member 80 (pad electrode 52p). The predetermined portion 70c of the bonding wire 70 is electrically connected to the outer shield electrode 54. In this manner, the side surface shield electrode 55 is electrically connected to the ground layer 51g through the top surface shield electrode 60, the bonding wire 70, and the outer shield electrode 54. In addition, the side surface shield electrode 55 is electrically connected to the ground layer 51g through the top surface shield electrode 60, the bonding wire 70, and the conductive member 80. That is, the side surface shield electrode 55 is electrically connected to the ground layer 51g by two conductive paths. Therefore, discharge performance from the side surface shield electrode 55 to the ground layer 51g is improved, and as a result, shielding performance of the side surface shield electrode 55 is improved. In this manner, the side surface shield electrode 55 can further reduce the interference of the electromagnetic waves (signals) between the first electronic component 50A and the second electronic component 50B.

### (2) Advantageous Effects

The high frequency module 1 according to Embodiment 4 further includes the conductive member 80. The conductive member 80 is provided on the first main surface 51a of the mounting substrate 51, and is connected to the ground layer 51g. The bonding wire 70 further includes the second end portion 70b different from the first end portion 70a. The second end portion 70b of the bonding wire 70 is connected to the conductive member 80.

According to this configuration, it is possible to secure two paths of a first path via the outer shield electrode 54 and a second path via the conductive member 80, as paths for connecting the side surface shield electrode 55 to the ground layer 51g. In this manner, electromagnetic shielding performance of the side surface shield electrode 55 can be improved.

In addition, in the high frequency module 1 according to Embodiment 4, the conductive member 80 is the pad electrode 52p. The pad electrode 52p is disposed on the first main surface 51a of the mounting substrate 51. According to this configuration, since the pad electrode 52p (existing conductive member 80) disposed on the first main surface 51a of the mounting substrate 51 can be used as the conductive member 80, it is possible to avoid a size increase in the high frequency module 1.

### (3) Modification Example

Modification examples of Embodiment 4 will be described. The modification examples described below can be implemented in combination. In addition, the following modification examples can be implemented in combination with Embodiments 1 to 3 and the modification examples thereof.

### (3-1) Modification Example 1

In Modification Example 1, another specific example of the conductive member 80 of Embodiment 4 will be described.

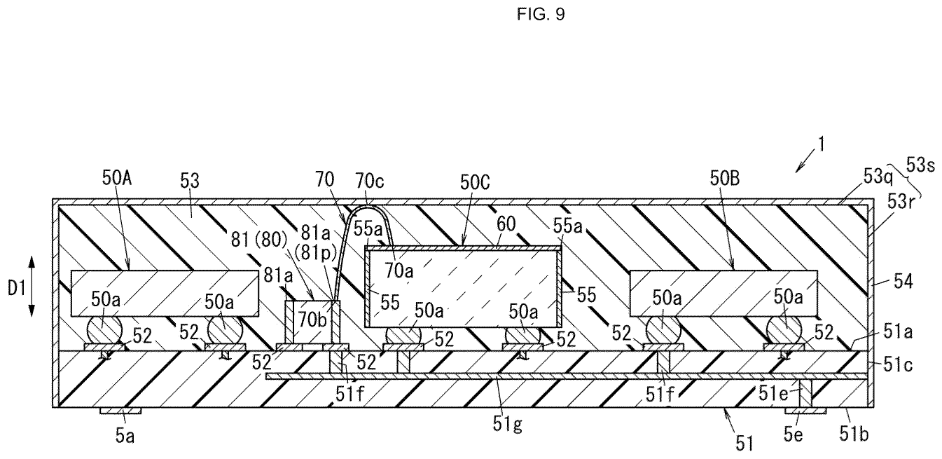

As shown in FIG. 9, the conductive member 80 of Modification Example 1 is an outer electrode 81p of a predetermined electronic component 81 disposed on the first main surface 51a of the mounting substrate 51.

The predetermined electronic component 81 is different from the first electronic component 50A, the second electronic component 50B, and the third electronic component 50C. For example, the predetermined electronic component 81 is a capacitor, an inductor, and the like. The predetermined electronic component 81 includes a plurality of (in the example in FIG. 9, two) outer electrodes 81a. The plurality of outer electrodes 81a are connected to the plurality of pad electrodes 52 provided on the first main surface 51a of the mounting substrate 51 by soldering, for example. The outer electrode 81p is the ground electrode electrically connected to the ground layer 51g of the mounting substrate 51 in the plurality of outer electrodes 81a. That is, the outer electrode 81p is electrically connected to the ground layer 51g of the mounting substrate 51 with the pad electrode 52 and the via electrode of the mounting substrate 51 interposed therebetween.

The second end portion 70b of the bonding wire 70 of Modification Example 1 is electrically connected to the ground layer 51g of the mounting substrate 51 with the outer electrode 81p which is the conductive member 80 interposed therebetween.

In Modification Example 1, the conductive member 80 is the outer electrode 81p. The outer electrode 81p is the outer electrode of the predetermined electronic component 81 disposed on the first main surface 51a of the mounting substrate 51. According to this configuration, the second end portion 70b of the bonding wire 70 can be connected to the ground layer 51g by using the outer electrode 81p of the predetermined electronic component 81 disposed on the first main surface 51a of the mounting substrate 51.

### (3-2) Modification Example 2

In Modification Example 1, still another specific example of the conductive member 80 of Embodiment 4 will be described.

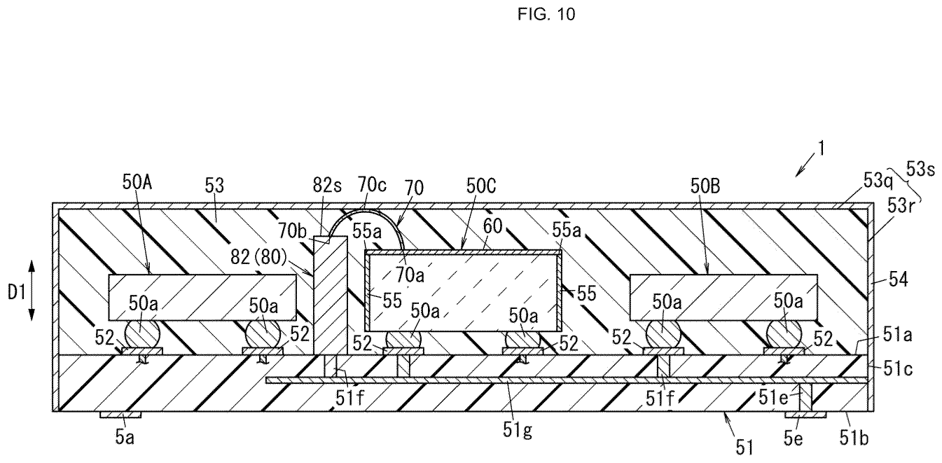

As shown in FIG. 10, the conductive member 80 of Modification Example 2 is an electromagnetic shielding metal wall 82 provided on the first main surface 51a of the mounting substrate 51.

The metal wall 82 is a wall portion formed of a conductive metal. The metal wall 82 is electrically connected to the ground layer 51g of the mounting substrate 51 with the via electrode of the mounting substrate 51 interposed therebetween. The metal wall 82 is disposed between the two electronic components 50, and is a member for shielding the two electronic components 50 from the electromagnetic waves flying between the two electronic components 50. In the example in FIG. 10, the metal wall 82 is disposed between the first electronic component 50A and the third electronic component 50C. In the example in FIG. 10, the top surface 82s of the metal wall 82 is not in contact with the outer shield electrode 54, but may be in contact with the outer shield electrode 54. The top surface 82s is an end surface on a side opposite to the side of the mounting substrate 51 in the metal wall 82.

For example, the second end portion 70b of the bonding wire 70 is electrically connected to the top surface 82s of the metal wall 82 which is the conductive member 80. Without being limited to the top surface 82s, a connection destination of the second end portion 70b may be connected to any portion of the metal wall 82. The second end portion 70b of the bonding wire 70 is electrically connected to the ground layer 51g of the mounting substrate 51 with the metal wall 82 interposed therebetween.

In Modification Example 2, the conductive member 80 is the shielding metal wall 82. The shielding metal wall 82 is provided on the first main surface 51a of the mounting substrate 51. According to this configuration, the second end portion 70b of the bonding wire 70 can be connected to the ground layer 51g by using the metal wall 82 provided on the first main surface 51a of the mounting substrate 51.

### Embodiment 5

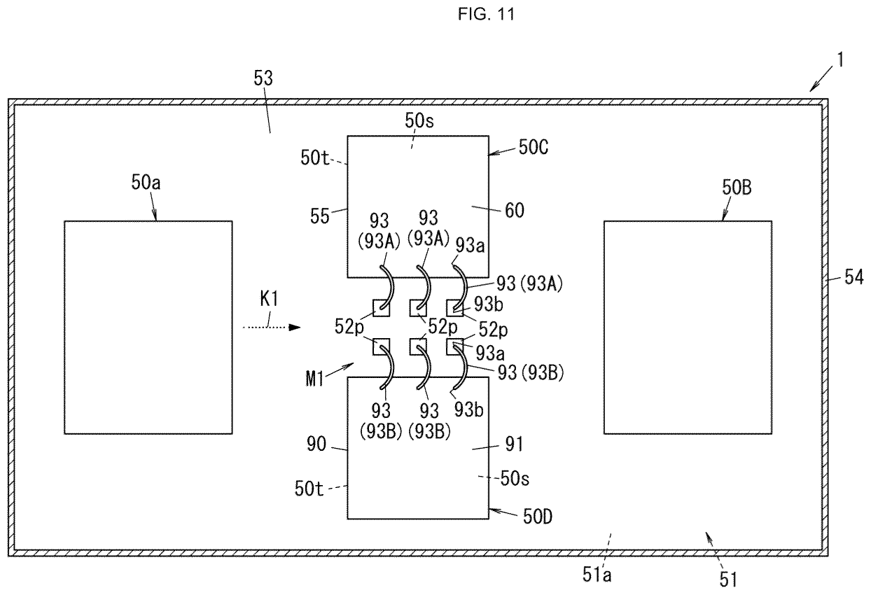

The high frequency module 1 according to Embodiment 5 will be described with reference to FIG. 11. In the following description, the same reference numerals as those in Embodiment 4 will be assigned to the same components as those in Embodiment 4, and description thereof will be omitted. In some cases, only the components different from those in Embodiment 4 will be described. In Embodiment 5, the side surface shield electrode 55 of Embodiment 4 will be referred to as a first side surface shield electrode 55, and the top surface shield electrode 60 of Embodiment 4 will be referred to as a first top surface shield electrode 60.

### (1) Configuration

As shown in FIG. 11, the high frequency module 1 according to Embodiment 5 further includes a fourth electronic component 50D, a second side surface shield electrode 90, a second top surface shield electrode 91, and at least one (in the example in FIG. 10, six) bonding wire 93 in the high frequency module 1 according to Embodiment 4.

As in the case of Embodiment 4, the third electronic component 50C of Embodiment 5 is disposed between the first electronic component 50A and the second electronic component 50B. In addition, as in the case of Embodiment 4, the third electronic component 50C of Embodiment 5 includes the first side surface shield electrode 55 and the first top surface shield electrode 60. The first side surface shield electrode 55 is provided on the outer peripheral surface of the third electronic component 50C. The first top surface shield electrode 60 is provided on the top surface of the third electronic component 50C, and is electrically connected to the first side surface shield electrode 55.

The fourth electronic component 50D is disposed between the first electronic component 50A and the second electronic component 50B on the first main surface 51a of the mounting substrate 51, and is adjacent to the third electronic component 50C. Here, the description of “A is adjacent to B” means that another electronic component is not disposed between A and B. More specifically, in a plan view in the thickness direction of the mounting substrate 51, the fourth electronic component 50D are aligned in a direction in which the first electronic component 50A and the second electronic component 50B are aligned, that is, a direction of intersecting (for example, an orthogonal direction, up-down direction on the paper surface in FIG. 11) a facing direction (right-left direction of the paper surface in FIG. 11) of the first electronic component 50A and the second electronic component 50B.

The second side surface shield electrode 90 is provided on at least one side surface (entire outer peripheral surface in the example in FIG. 11) of the fourth electronic component 50D. The second side surface shield electrode 90 is provided on the outer peripheral surface of the fourth electronic component 50D. The second top surface shield electrode 91 is provided in at least a portion of the top surface (in the example in FIG. 11, the entire top surface) of the fourth electronic component 50D. The second top surface shield electrode 91 is provided in at least a portion of the top surface (in the example in FIG. 11, the entire top surface) of the fourth electronic component 50D, and is electrically connected to the second side surface shield electrode 90.

The bonding wire 93 includes a first end portion 93a and a second end portion 93b which are different from each other. The first end portion 93a of the bonding wire 93 is electrically connected to the first top surface shield electrode 60 or the second top surface shield electrode 91. The second end portion 93b of the bonding wire 93 is electrically connected to the pad electrode 52p. The pad electrode 52p is a pad electrode disposed between the third electronic component 50C and the fourth electronic component 50D on the first main surface 51a of the mounting substrate 51. The pad electrode 52p is electrically connected to the ground layer of the mounting substrate 51.

The plurality of bonding wires 93 include a first predetermined number of (for example, three) bonding wires 93A and a second predetermined number of (for example, three) bonding wires 93B. The first end portion 93a of each of the bonding wires 93A is electrically connected to the first top surface shield electrode 60. The second end portion 93b of each of the bonding wires 93A is connected to the pad electrode 52p. The first end portion 93a of each of the bonding wires 93B is electrically connected to the second top surface shield electrode 91. The second end portion 93b of each of the bonding wires 93B is connected to the pad electrode 52p.

The entire bonding wire 93 is covered with the resin member 53 (refer to FIG. 8). Therefore, the bonding wire 93 is not in contact with the outer shield electrode 54. The bonding wire 93 may be in contact with the outer shield electrode 54.

The bonding wire 93 is disposed between the third electronic component 50C and the fourth electronic component 50D. The first end portion 93a of the bonding wire 93 is electrically connected to the ground layer of the mounting substrate 51 with the first top surface shield electrode 60 and the first side surface shield electrode 55 interposed therebetween, or is electrically connected to the ground layer of the mounting substrate 51 with the second top surface shield electrode 91 and the second side surface shield electrode 90 interposed therebetween. In addition, the second end portion 93b of the bonding wire 93 is electrically connected to the ground layer of the mounting substrate 51 with the pad electrode 52p interposed therebetween. Therefore, the bonding wire 93 has a function of shielding the electronic components from electromagnetic waves K1 passing through a gap M1 between the first electronic component 50A and the second electronic component 50B. In this manner, the electromagnetic waves K1 emitted from the first electronic component 50A and passing through the gap M1 are suppressed by the bonding wire 93 at a time of passing therethrough. As a result, the interference of the electromagnetic waves K1 between the first electronic component 50A and the second electronic component 50B can be further reduced.

### (2) Advantageous Effects

The high frequency module 1 according to Embodiment 5 includes the first top surface shield electrode 60, the fourth electronic component 50D, the second side surface shield electrode 90, the second top surface shield electrode 91, and the bonding wire 93. The first top surface shield electrode 60 is provided on the main surface 50s on a side opposite to the side of the mounting substrate 51 in the third electronic component 50C, and is connected to the first side surface shield electrode 55 which is the side surface shield electrode 55. The fourth electronic component 50D is disposed between the first electronic component 50A and the second electronic component 50B on the first main surface 51a of the mounting substrate 51, and is adjacent to the third electronic component 50C. The second side surface shield electrode 90 is provided on at least one side surface of the fourth electronic component 50D, and is connected to the ground layer 51g. The second top surface shield electrode 91 is provided on the main surface 50s on the side opposite to the side of the mounting substrate 51 in the fourth electronic component 50D, and is connected to the second side surface shield electrode 90. The bonding wire 93 includes the first end portion 93a and the second end portion 93b. The first end portion 93a of the bonding wire 93 is connected to the first top surface shield electrode 60 or the second top surface shield electrode 91. The second end portion 93b of the bonding wire 93 is connected to the pad electrode 52p provided between the third electronic component 50C and the fourth electronic component 50D on the first main surface 51a of the mounting substrate 51.

According to this configuration, the bonding wire 93 can electromagnetically shield the gap M1 between the third electronic component 50C and the fourth electronic component 50D. As a result, the interference of the electromagnetic waves between the first electronic component 50A and the second electronic component 50B can be further reduced.

### Embodiment 6

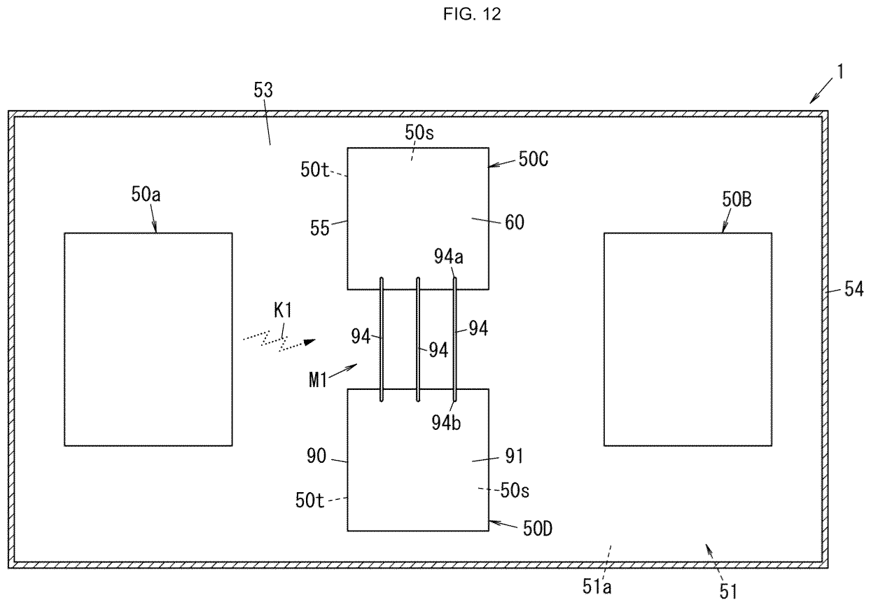

The high frequency module 1 according to Embodiment 6 will be described with reference to FIG. 12. In the following description, the same reference numerals as those in Embodiment 1 will be assigned to the same components as those in Embodiment 5, and description thereof will be omitted. In some cases, only the components different from those in Embodiment 5 will be described.

### (1) Configuration

As shown in FIG. 12, as in the case of Embodiment 5, the high frequency module 1 according to Embodiment 6 includes the fourth electronic component 50D, the second side surface shield electrode 90, the second top surface shield electrode 91, and at least one (in the example in FIG. 12, three) bonding wire 94.

The third electronic component 50C and the fourth electronic component 50D of Embodiment 6 are configured and disposed in the same manner as the third electronic component 50C and the fourth electronic component 50D of Embodiment 5.

The bonding wire 94 includes a first end portion 94a and a second end portion 94b which are different from each other. The first end portion 94a of the bonding wire 94 is electrically connected to the first top surface shield electrode 60, and the second end portion 94b of the bonding wire 94 is electrically connected to the second top surface shield electrode 91. That is, the bonding wire 94 is provided across the first top surface shield electrode 60 and the second top surface shield electrode 91.

The entire bonding wire 94 is covered with the resin member 53 (refer to FIG. 8). Therefore, the bonding wire 94 is not in contact with the outer shield electrode 54.

The bonding wire 94 is provided across the third electronic component 50C and the fourth electronic component 50D. The first end portion 94a of the bonding wire 94 is electrically connected to the ground layer of the mounting substrate 51 with the first top surface shield electrode 60 and the first side surface shield electrode 55 interposed therebetween. The second end portion 94b of the bonding wire 94 is electrically connected to the ground layer of the mounting substrate 51 with the second top surface shield electrode 91 and the second side surface shield electrode 90 interposed therebetween. Therefore, the bonding wire 94 has a function of shielding the electronic components from the electromagnetic waves K1 passing through the gap M1 between the first electronic component 50A and the second electronic component 50B. In this manner, the electromagnetic waves K1 emitted from the first electronic component 50A and passing through the gap M1 are suppressed by the bonding wire 94 at a time of passing therethrough. As a result, the interference of the electromagnetic waves K1 between the first electronic component 50A and the second electronic component 50B can be further reduced.

### (2) Advantageous Effects

The high frequency module 1 according to Embodiment 6 includes the first top surface shield electrode 60, the fourth electronic component 50D, the second side surface shield electrode 90, the second top surface shield electrode 91, and the bonding wire 94. The first top surface shield electrode 60 is provided on the main surface 50s on a side opposite to the side of the mounting substrate 51 in the third electronic component 50C, and is connected to the first side surface shield electrode 55 which is the side surface shield electrode 55. The fourth electronic component 50D is disposed between the first electronic component 50A and the second electronic component 50B on the first main surface 51a of the mounting substrate 51, and is adjacent to the third electronic component 50C. The second side surface shield electrode 90 is provided on at least one side surface 50u or 50v of the fourth electronic component 50D, and is connected to the ground layer 51g. The second top surface shield electrode 91 is provided on the main surface 50s on the side opposite to the side of the mounting substrate 51 in the fourth electronic component 50D, and is connected to the second side surface shield electrode 90. The bonding wire 94 includes the first end portion 94a and the second end portion 94b. The first end portion 94a of the bonding wire 94 is connected to the first top surface shield electrode 60. The second end portion 94b of the bonding wire 94 is connected to the second top surface shield electrode 91.

According to this configuration, the bonding wire 94 can electromagnetically shield the gap M1 between the third electronic component 50C and the fourth electronic component 50D. As a result, the interference of the electromagnetic waves between the first electronic component 50A and the second electronic component 50B can be further reduced.

### (3) Modification Example

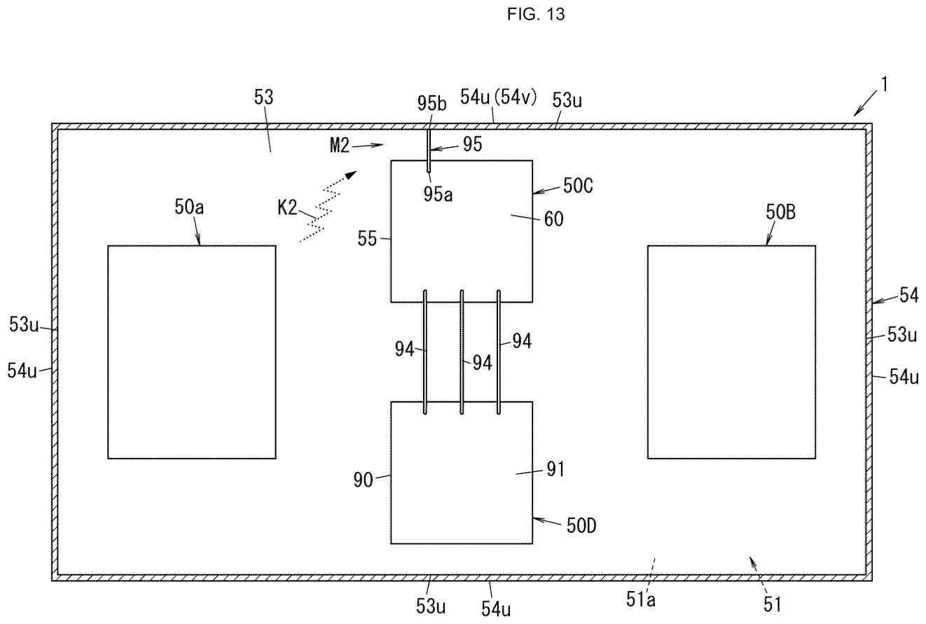

Modification examples of Embodiment 6 will be described with reference to FIG. 13. The modification examples described below can be implemented in combination with Embodiments 1 to 5 and the modification examples thereof.

### (3-1) Modification Example 1

### (3-1-1) Configuration

As shown in FIG. 13, the high frequency module 1 according to Modification Example 1 further includes at least one bonding wire 95 in the high frequency module 1 according to Embodiment 6.

The outer shield electrode 54 has a plurality of (four in the example in FIG. 13) side surface portions 54u. The resin member 53 has a polygonal (in the example in FIG. 13, quadrangular) shape in a plan view in the thickness direction of the mounting substrate 51. That is, the outer peripheral surface of the resin member 53 has a plurality of (four in the example in FIG. 13) side surfaces 53u. The plurality of side surface portions 54u of the outer shield electrode 54 correspond one-to-one to the plurality of side surfaces 53u of the resin member 53, and are provided on the corresponding side surfaces 53u.

The third electronic component 50C is disposed adjacent to one side surface portion 54v in the plurality of side surface portions 54u of the outer shield electrode 54.

The bonding wire 95 has a first end portion 95a and a second end portion 95b which are different from each other. The first end portion 95a of the bonding wire 95 is electrically connected to the first top surface shield electrode 60 of the third electronic component 50C, and the second end portion 95b of the bonding wire 95 is electrically connected to one side surface portion 54v of the outer shield electrode 54.

The entire bonding wire 95 is covered with the resin member 53. Therefore, the bonding wire 95 is not in contact with the outer shield electrode 54.

The bonding wire 95 is provided across the first top surface shield electrode 60 of the third electronic component 50C and the one side surface portion 54v of the outer shield electrode 54. The first end portion 95a of the bonding wire 95 is electrically connected to the ground layer of the mounting substrate 51 with the first top surface shield electrode 60 and the first side surface shield electrode 55 interposed therebetween. The second end portion 95b of the bonding wire 95 is electrically connected to the ground layer of the mounting substrate 51 with one side surface portion 54v (that is, the outer shield electrode 54) interposed therebetween. Therefore, the bonding wire 95 has a function of shielding the electronic components from the electromagnetic waves K2 emitted from the first electronic component 50A and passing through a gap M2 between the first electronic component 50A and the one side surface portion 54v. In this manner, the electromagnetic waves K2 emitted from the first electronic component 50A and passing through the gap M2 are suppressed by the bonding wire 95 at a time of passing therethrough. As a result, the interference of the electromagnetic waves between the first electronic component 50A and the second electronic component 50B can be further reduced.

### (3-1-2) Advantageous Effects

The high frequency module 1 according to Modification Example 1 includes the resin member 53, the outer shield electrode 54, the top surface shield electrode 60, and the bonding wire 95. The resin member 53 is provided on the first main surface 51a to cover the first electronic component 50A, the second electronic component 50B, the third electronic component 50C, and the side surface shield electrode 55. The outer shield electrode 54 is provided on at least the outer surface 53s of the resin member 53, and is connected to the ground layer 51g. The top surface shield electrode 60 is provided on the main surface 50s on a side opposite to the side of the mounting substrate 51 in the third electronic component 50C, and is connected to the side surface shield electrode 55. The bonding wire 95 has the first end portion 95a and the second end portion 95b. The outer shield electrode 54 has the plurality of side surface portions 54u. The plurality of side surface portions 54u are provided on the plurality of side surfaces 53u of the resin member 53. The third electronic component 50C is adjacent to one side surface portion 54v in the plurality of side surface portions 54u. The first end portion 95a of the bonding wire 95 is connected to the top surface shield electrode 60 provided in the third electronic component 50C. The second end portion 95b of the bonding wire 95 is electrically connected to one side surface portion 54v of the outer shield electrode 54.

According to this configuration, the bonding wire 95 can electromagnetically shield the gap M2 between the side surface portion 54v adjacent to the third electronic component 50C and the third electronic component 50C in the plurality of side surface portions 54u of the outer shield electrode 54. As a result, the interference of the electromagnetic waves between the first electronic component 50A and the second electronic component 50B can be further reduced.

### Embodiment 7

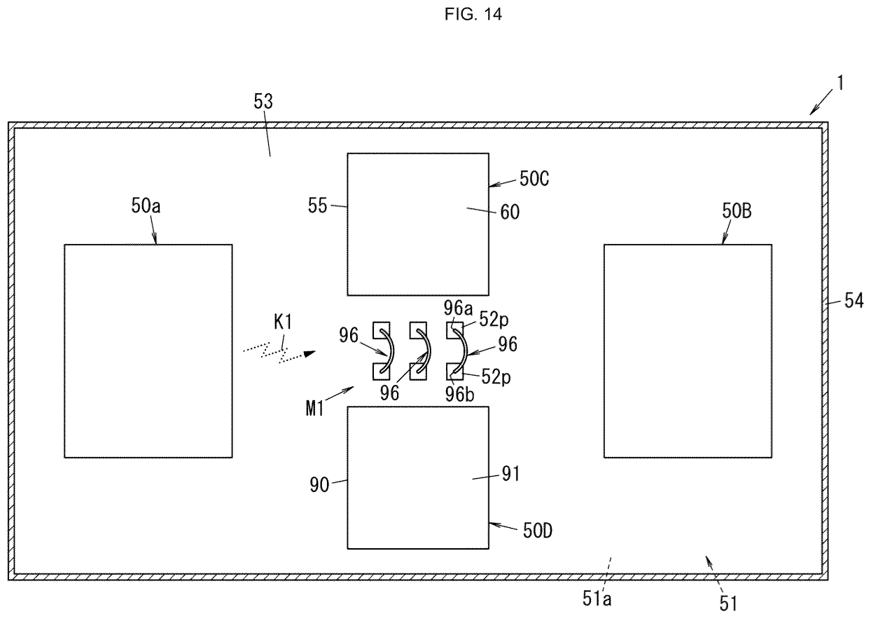

The high frequency module 1 according to Embodiment 7 will be described with reference to FIG. 14. In the following description, the same reference numerals as those in Embodiment 1 will be assigned to the same components as those in Embodiment 5, and description thereof will be omitted. In some cases, only the components different from those in Embodiment 5 will be described.

### (1) Configuration

As shown in FIG. 14, as in the case of Embodiment 5, the high frequency module 1 according to Embodiment 7 includes the fourth electronic component 50D, the second side surface shield electrode 90, the second top surface shield electrode 91, and at least one (in the example in FIG. 14, three) bonding wire 96.

The third electronic component 50C and the fourth electronic component 50D of Embodiment 7 are configured and disposed in the same manner as the third electronic component 50C and the fourth electronic component 50D of Embodiment 5.

The bonding wire 96 is disposed between the third electronic component 50C and the fourth electronic component 50D on the first main surface 51a of the mounting substrate 51. The bonding wire 96 has a first end portion 96a and a second end portion 96b which are different from each other. The first end portion 96a and the second end portion 96b of the bonding wire 96 are electrically connected to the pad electrodes 52p different from each other. The pad electrode 52p is the pad electrode 52 disposed between the third electronic component 50C and the fourth electronic component 50D on the first main surface 51a of the mounting substrate 51, and is electrically connected to the ground layer of the mounting substrate 51.

The entire bonding wire 96 is covered with the resin member 53. Therefore, the bonding wire 96 is not in contact with the outer shield electrode 54. A portion of the bonding wire 96 may be in contact with the outer shield electrode 54.

The bonding wire 96 is provided on the first main surface 51a of the mounting substrate 51 in a state of being bent in an inverted U-shape between the third electronic component 50C and the fourth electronic component 50D. Each of the first end portion 96a and the second end portion 96b of the bonding wire 96 are electrically connected to the ground layer of the mounting substrate 51 with the pad electrode 52p interposed therebetween. Therefore, the bonding wire 96 has a function of shielding the electronic components from the electromagnetic waves K1 emitted from the first electronic component 50A and passing through the gap M1 between the first electronic component 50A and the second electronic component 50B. In this manner, the electromagnetic waves K1 emitted from the first electronic component 50A and passing through the gap M1 are suppressed by the bonding wire 96 at a time of passing therethrough. As a result, the interference of the electromagnetic waves between the first electronic component 50A and the second electronic component 50B can be further reduced.

### (2) Advantageous Effects

The high frequency module 1 according to Embodiment 7 includes the fourth electronic component 50D and the bonding wire 96. The fourth electronic component 50D is disposed between the first electronic component 50A and the second electronic component 50B on the first main surface 51a of the mounting substrate 51, and is adjacent to the third electronic component 50C. The bonding wire 96 is provided between the third electronic component 50C and the fourth electronic component 50D on the first main surface 51a of the mounting substrate 51. Both ends (first end portion 96a and second end portion 96b) of the bonding wire 96 are connected to the pad electrode 52p. The pad electrode 52p is provided between the third electronic component 50C and the fourth electronic component 50D on the first main surface 51a of the mounting substrate 51, and is connected to the ground layer 51g.

According to this configuration, the bonding wire 96 can electromagnetically shield the gap M1 between the third electronic component 50C and the fourth electronic component 50D. As a result, the interference of the electromagnetic waves between the first electronic component 50A and the second electronic component 50B can be further reduced.

### Embodiment 8

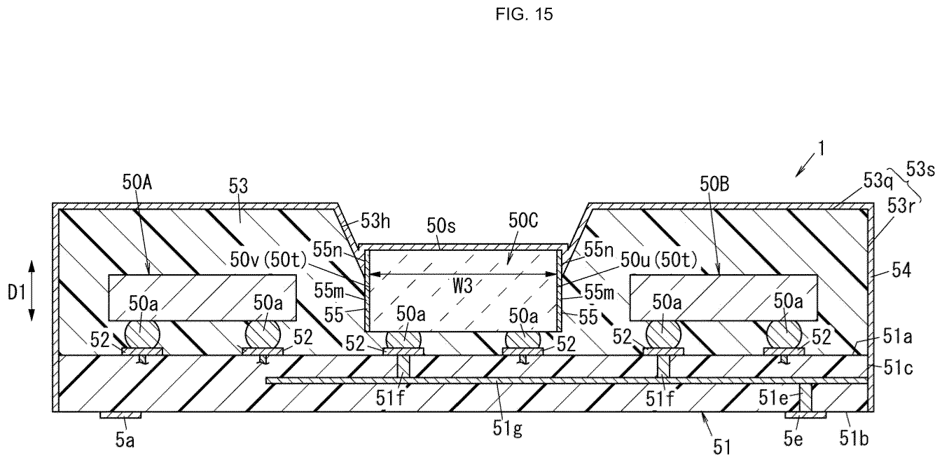

The high frequency module 1 according to Embodiment 8 will be described with reference to FIG. 15. In the following description, the same reference numerals as those in Embodiment 1 will be assigned to the same components as those in Embodiment 1, and description thereof will be omitted. In some cases, only the components different from those in Embodiment 1 will be described.

### (1) Configuration

The high frequency module 1 according to Embodiment 8 is configured in the same manner as the high frequency module 1 according to Embodiment 1, except that the outer shield electrode 54 is in direct contact with a main surface 55m of the side surface shield electrode 55. Hereinafter, Embodiment 8 will be described in detail.

In Embodiment 8, as in the case of Embodiment 1, the side surface shield electrode 55 is provided on the outer peripheral surface 50t of the third electronic component 50C.

In Embodiment 8, as in the case of Embodiment 1, the resin member 53 is provided on the first main surface 51a of the mounting substrate 51 to cover the plurality of electronic components 50. In this manner, the resin member 53 covers the top surface 50s of the third electronic component 50C.

The resin member 53 has a through hole 53h. The side surface shield electrode 55 has the main surface 55m. The main surface 55m is the main surface of the side surface shield electrode 55 in the outer side portion (side opposite to the side of the outer peripheral surface 50t of the third electronic component 50C) in the thickness direction. The through hole 53h is provided in the resin member 53 such that a predetermined region 55n on the main surface 55m of the side surface shield electrode 55 is exposed from the top surface 53q of the resin member 53. That is, the through hole 53h is provided in the resin member 53 to penetrate between the top surface 53q of the resin member 53 and the predetermined region 55n of the side surface shield electrode 55. The predetermined region 55n of the side surface shield electrode 55 may be the entire main surface 55m of the side surface shield electrode 55, or may be a portion of the region of the main surface 55m. In the example in FIG. 15, the predetermined region 55n is a portion (for example, an edge portion) on a side of the top surface 50s of the third electronic component 50C on the main surface 55m.

More specifically, in the example in FIG. 15, the side surface shield electrode 55 is provided on each of the first side surface 50u and the second side surface 50v of the outer peripheral surface 50t of the third electronic component 50C. The first side surface 50u and the second side surface 50v are side surfaces facing the first electronic component 50A or the second electronic component 50B in the plurality of (for example, four) side surfaces forming the outer peripheral surface 50t of the third electronic component 50C. The through hole 53h exposes the predetermined region 55n of the side surface shield electrode 55 provided on each of the first side surface 50u and the second side surface 50v from the top surface 53q of the resin member 53. Furthermore, the through hole 53h exposes an entire width W3 of the top surface 50s of the third electronic component 50C from the top surface 53q of the resin member 53. Here, the width W3 is the width between the first side surface 50u and the second side surface 50v on the top surface 50s of the third electronic component 50C.

In a vertical direction on the paper surface in FIG. 15, the through hole 53h may entirely or partially expose the main surface 55m of the side surface shield electrode 55. Similarly, in the vertical direction on the paper surface in FIG. 15, the through hole 53h may entirely or partially expose the top surface 50s of the third electronic component 50C.

As in the case of Embodiment 1, the outer shield electrode 54 covers the outer surface 53s of the resin member 53 and the outer peripheral surface 51c of the mounting substrate 51. Furthermore, the outer shield electrode 54 covers the inner peripheral surface of the through hole 53h, the predetermined region 55n of each side surface shield electrode 55, and the entire width W3 of the top surface 50s of the third electronic component 50C. The outer shield electrode 54 is electrically connected to each side surface shield electrode 55 by covering (that is, coming into contact with) the predetermined region 55n of each side surface shield electrode 55. In this manner, a contact area between the outer shield electrode 54 and the side surface shield electrode 55 can be increased, and electromagnetic shielding performance of the side surface shield electrode 55 can be improved.

### (2) Advantageous Effects

In the high frequency module 1 according to Embodiment 8, the resin member 53 has the through hole 53h. The through hole 53h exposes the predetermined region 55n of the main surface 55m of the side surface shield electrode 55 of the third electronic component 50C. The outer shield electrode 54 further covers the inner peripheral surface of the through hole 53h and the predetermined region 55n of the side surface shield electrode 55. The outer shield electrode 54 is electrically connected to the side surface shield electrode 55 by coming into contact with the predetermined region 55n.

According to this configuration, since the outer shield electrode 54 is in direct contact with the predetermined region 55n of the main surface 55m of the side surface shield electrode 55, the contact area with the side surface shield electrode 55 can be increased. In this manner, conductivity between the side surface shield electrode 55 and the outer shield electrode 54 can be improved, and shielding performance of the side surface shield electrode 55 can be improved.

### ASPECTS

The following aspects are disclosed in the present specification.

The high frequency module (1) according to a first aspect includes the mounting substrate (51), the first electronic component (50A), the second electronic component (50B), the third electronic component (50C), and the side surface shield electrode (55). The mounting substrate (51) has the first main surface (51a) and the second main surface (51b) which face each other. The first electronic component (50A) is disposed on the first main surface (51a) of the mounting substrate (51). The second electronic component (50B) is disposed on the first main surface (51a) of the mounting substrate (51). The third electronic component (50C) is disposed between the first electronic component (50A) and the second electronic component (50B) on the first main surface (51a) of the mounting substrate (51). The side surface shield electrode (55) is provided on at least one side surface (50u or 50v) of the third electronic component (50C). The mounting substrate (51) includes the ground layer (51g). The side surface shield electrode (55) is connected to the ground layer (51g).

According to this configuration, the interference of the electromagnetic waves (signals) between the first electronic component (50A) and the second electronic component (50B) can be reduced by the side surface shield electrode (55) provided on the outer peripheral surface (50t) of the third electronic component (50C). In addition, since the side surface shield electrode (55) is disposed by using the outer peripheral surface (50t) of the third electronic component (50C), it is not necessary to secure a disposition space for disposing the shield wall on the first main surface (51a) of the mounting substrate (51), compared to a case that the shield wall is disposed separately from the third electronic component (50C). As a result, the high frequency module (1) can achieve size reduction.

In the first aspect, the high frequency module (1) according to a second aspect further includes the resin member (53) and the outer shield electrode (54). The resin member (53) is provided on the first main surface (51a) of the mounting substrate (51) to cover the first electronic component (50A), the second electronic component (50B), the third electronic component (50C), and the side surface shield electrode (55). The outer shield electrode (54) is provided on at least the outer surface (53s) of the resin member (53), and is connected to the ground layer (51g). The side surface shield electrode (55) is connected to the outer shield electrode (54).

According to this configuration, the side surface shield electrode (55) can be connected to the ground layer (51g) of the mounting substrate (51) with a simple structure by using the outer shield electrode (54).

In the second aspect, the high frequency module (1) according to a third aspect further includes the top surface shield electrode (60) and the connection member (61 or 61A). The top surface shield electrode (60) is provided on the main surface (50s) on a side opposite to the side of the mounting substrate (51) in the third electronic component (50C), and is connected to the side surface shield electrode (55). The connection member (61 or 61A) connects the top surface shield electrode (60) and the outer shield electrode (54).

According to this configuration, the side surface shield electrode (55) and the outer shield electrode (54) can be connected by the connection member (61 or 61A) without exposing the entire top surface (main surface on the side opposite to the side of the mounting substrate (51)) (50s) in the third electronic component (50C) from the resin member (53).

In the second aspect, the high frequency module (1) according to a fourth aspect further includes the top surface shield electrode (60) and the bonding wire (70). The top surface shield electrode (60) is provided on the main surface (50s) on a side opposite to the side of the mounting substrate (51) in the third electronic component (50C), and is connected to the side surface shield electrode (55). The bonding wire (70) has the first end portion (70a) and the predetermined portion (70c). The predetermined portion (70c) is a portion different from the first end portion (70a). The first end portion (70a) of the bonding wire (70) is connected to the top surface shield electrode (60), and the predetermined portion (70c) of the bonding wire (70) is connected to the outer shield electrode (54).

According to this configuration, the side surface shield electrode (55) and the outer shield electrode (54) can be connected by the bonding wire (70) without exposing the entire top surface (main surface on the side opposite to the side of the mounting substrate (51)) (50s) of the third electronic component (50C) from the resin member (53).

In the fourth aspect, the high frequency module (1) according to a fifth aspect further includes the conductive member (80). The conductive member (80) is provided on the first main surface (51a) of the mounting substrate (51), and is connected to the ground layer (51g). The bonding wire (70) further has the second end portion (70b) different from the first end portion (70a). The second end portion (70b) of the bonding wire (70) is connected to the conductive member (80).

According to this configuration, it is possible to secure two paths of the first path via the outer shield electrode (54) and the second path via the conductive member (80), as paths for connecting the side surface shield electrode (55) to the ground layer (51g). In this manner, electromagnetic shielding performance of the side surface shield electrode (55) can be improved.

In the fifth aspect, in the high frequency module (1) according to a sixth aspect, the conductive member (80) is the pad electrode (52p), the outer electrode (81a), or the shielding metal wall (82). The pad electrode (52p) is disposed on the first main surface (51a) of the mounting substrate (51). The outer electrode (81a) is the outer electrode (81a) of the predetermined electronic component (81) disposed on the first main surface (51a) of the mounting substrate (51) and different from the first electronic component (50A), the second electronic component (50B), and the third electronic component (50C). The shielding metal wall (82) is provided on the first main surface (51a) of the mounting substrate (51).

According to this configuration, since the existing conductive member (80) disposed on the first main surface (51a) of the mounting substrate (51) can be used as the conductive member (80), it is possible to avoid a size increase in the high frequency module (1).

In any one of the first to third aspects, the high frequency module (1) according to a seventh aspect further includes the first top surface shield electrode (60), the fourth electronic component (50D), the second side surface shield electrode (90), the second top surface shield electrode (91), and the bonding wire (93). The first top surface shield electrode (60) is provided on the main surface (50s) on the side opposite to the side of the mounting substrate (51) in the third electronic component (50C), and is connected to the first side surface shield electrode (55) which is the side surface shield electrode (55). The fourth electronic component (50D) is disposed between the first electronic component (50A) and the second electronic component (50B) on the first main surface (51a) of the mounting substrate (51), and is adjacent to the third electronic component (50C). The second side surface shield electrode (90) is provided on at least one side surface of the fourth electronic component (50D), and is connected to the ground layer (51g). The second top surface shield electrode (91) is provided on the main surface (50s) on the side opposite to the side of the mounting substrate (51) in the fourth electronic component (50D), and is connected to the second side surface shield electrode (90). The bonding wire (93) has the first end portion (93a) and the second end portion (93b). The first end portion (93a) of the bonding wire (93) is connected to the first top surface shield electrode (60) or the second top surface shield electrode (91). The second end portion (93b) of the bonding wire (93) is connected to the pad electrode (52p) provided between the third electronic component (50C) and the fourth electronic component (50D) on the first main surface (51a) of the mounting substrate (51).

According to this configuration, the bonding wire (93) can electromagnetically shield the gap (M1) between the third electronic component (50C) and the fourth electronic component (50D). As a result, the interference of the electromagnetic waves between the first electronic component (50A) and the second electronic component (50B) can be further reduced.

In any one of the first to third aspects, the high frequency module (1) according to an eighth aspect further includes the first top surface shield electrode (60), the fourth electronic component (50D), the second side surface shield electrode (90), the second top surface shield electrode (91), and the bonding wire (94). The first top surface shield electrode (60) is provided on the main surface (50s) on the side opposite to the side of the mounting substrate (51) in the third electronic component (50C), and is connected to the first side surface shield electrode (55) which is the side surface shield electrode (55). The fourth electronic component (50D) is disposed between the first electronic component (50A) and the second electronic component (50B) on the first main surface (51a) of the mounting substrate (51), and is adjacent to the third electronic component (50C). The second side surface shield electrode (90) is provided on at least one side surface of the fourth electronic component (50D), and is connected to the ground layer (51g). The second top surface shield electrode (91) is provided on the main surface (50s) on the side opposite to the side of the mounting substrate (51) in the fourth electronic component (50D), and is connected to the second side surface shield electrode (90). The bonding wire (94) has the first end portion (94a) and the second end portion (94b). The first end portion (94a) of the bonding wire (94) is connected to the first top surface shield electrode (60). The second end portion (94b) of the bonding wire (94) is connected to the second top surface shield electrode (91).

According to this configuration, the bonding wire (94) can electromagnetically shield the gap (M1) between the third electronic component (50C) and the fourth electronic component (50D). As a result, the interference of the electromagnetic waves between the first electronic component (50A) and the second electronic component (50B) can be further reduced.

In any one of the first to third aspects, the high frequency module (1) according to a ninth aspect further includes the resin member (53), the outer shield electrode (54), the top surface shield electrode (60), and the bonding wire (95). The resin member (53) is provided on the first main surface (51a) to cover the first electronic component (50A), the second electronic component (50B), the third electronic component (50C), and the side surface shield electrode (55). The outer shield electrode (54) is provided on at least the outer surface (53s) of the resin member (53), and is connected to the ground layer (51g). The top surface shield electrode (60) is provided on the main surface (50s) on a side opposite to the side of the mounting substrate (51) in the third electronic component (50C), and is connected to the side surface shield electrode (55). The bonding wire (95) has the first end portion (95a) and the second end portion (95b). The outer shield electrode (54) has the plurality of side surface portions (54u). The plurality of side surface portions (54u) are provided on the plurality of side surfaces (53u) of the resin member (53). The third electronic component (50C) is adjacent to one side surface portion (54v) in the plurality of side surface portions (54u). The first end portion (95a) of the bonding wire (95) is connected to the top surface shield electrode (60) provided in the third electronic component (50C). The second end portion (95b) of the bonding wire (95) is connected to one side surface portion (54v) of the outer shield electrode (54).

According to this configuration, the bonding wire (95) can electromagnetically shield the gap (M2) between one side surface portion (54v) adjacent to the third electronic component (50C) in the plurality of side surface portions (54u) of the outer shield electrode (54) and the third electronic component (50C). As a result, the interference of the electromagnetic waves between the first electronic component (50A) and the second electronic component (50B) can be further reduced.

In any one of the first to third aspects, the high frequency module (1) according to a tenth aspect further includes the fourth electronic component (50D) and the bonding wire (96). The fourth electronic component (50D) is disposed between the first electronic component (50A) and the second electronic component (50B) on the first main surface (51a) of the mounting substrate (51), and is adjacent to the third electronic component (50C). The bonding wire (96) is provided between the third electronic component (50C) and the fourth electronic component (50D) on the first main surface (51a) of the mounting substrate (51). Both ends (96a and 96b) of the bonding wire (96) are connected to the pad electrode (52p). The pad electrode (52p) is provided between the third electronic component (50C) and the fourth electronic component (50D) on the first main surface (51a) of the mounting substrate (51), and is connected to the ground layer (51g).

According to this configuration, the bonding wire (96) can electromagnetically shield the gap (M1) between the third electronic component (50C) and the fourth electronic component (50D). As a result, the interference of the electromagnetic waves between the first electronic component (50A) and the second electronic component (50B) can be further reduced.

In the high frequency module (1) according to an eleventh aspect, in any one of the first to tenth aspects, the third electronic component (50C) is the acoustic wave filter (7 and 8) including the piezoelectric substrate.

According to this configuration, since the acoustic wave filter (7 or 8) is used for transmission and reception, in many cases, the acoustic wave filter (7 or 8) is disposed between the transmission area (R1) and the reception area (R2). Since the side surface shield electrode (55) is provided on the outer peripheral surface of the acoustic wave filter (7 or 8), isolation between the transmission area (R1) and the reception area (R2) can be improved without significantly changing the disposition of the component disposed on the mounting substrate (51).

In the high frequency module (1) according to the twelfth aspect, in any one of the second to tenth aspects, the resin member (53) has the through hole (53h). The through hole (53h) exposes the predetermined region (55n) of the main surface (55m) of the side surface shield electrode (55) of the third electronic component (50C). The outer shield electrode (54) further covers the inner peripheral surface of the through hole (53h) and the predetermined region (55n) of the side surface shield electrode (55). The outer shield electrode (54) is connected to the side surface shield electrode (55) by coming into contact with the predetermined region (55n).

According to this configuration, since the outer shield electrode (54) is in direct contact with the predetermined region (55n) of the main surface (55m) of the side surface shield electrode (55), a contact area with the side surface shield electrode (55) can be increased. In this manner, conductivity between the side surface shield electrode (55) and the outer shield electrode (54) can be improved, and shielding performance of the side surface shield electrode (55) can be improved.

The communication device (30) according to a thirteenth aspect includes the high frequency module (1) according to any one of the first to twelfth aspects and the signal processing circuit (2). The signal processing circuit (2) is connected to the high frequency module (1) to perform signal processing on the high frequency signal.

According to this configuration, the communication device (30) achieving the advantageous effects of the high frequency module (1) can be provided.

What is claimed is:

1. A high frequency module comprising:
a mounting substrate having a first main surface and a second main surface which face each other;
a first electronic component disposed on the first main surface of the mounting substrate, the first electronic component being one of a first filter, a first amplifier, or a first matching circuit;
a second electronic component disposed on the first main surface of the mounting substrate, the second electronic component being a second filter, a second amplifier, or a second matching circuit;
a third electronic component disposed between the first electronic component and the second electronic component on the first main surface of the mounting substrate, the third electronic component being an acoustic wave filter; and
a side surface shield electrode provided on at least one side surface of the third electronic component,
wherein the mounting substrate includes a ground layer, and
the side surface shield electrode is connected to the ground layer.

2. The high frequency module according to claim 1, further comprising:
a resin provided on the first main surface of the mounting substrate to cover the first electronic component, the second electronic component, the third electronic component, and the side surface shield electrode; and
an outer shield electrode provided on at least an outer surface of the resin and connected to the ground layer,
wherein the side surface shield electrode is connected to the outer shield electrode.

3. The high frequency module according to claim 2, further comprising:
a top surface shield electrode provided on a main surface on a side opposite to a side of the mounting substrate in the third electronic component and connected to the side surface shield electrode; and
a recessed conductor layer that connects the top surface shield electrode and the outer shield electrode.

4. The high frequency module according to claim 2, further comprising:
a top surface shield electrode provided on a main surface on a side opposite to a side of the mounting substrate in the third electronic component and connected to the side surface shield electrode; and
a bonding wire,
wherein the bonding wire has a first end portion and a predetermined portion which is a portion different from the first end portion,
the first end portion of the bonding wire is connected to the top surface shield electrode, and
the predetermined portion of the bonding wire is connected to the outer shield electrode.

5. The high frequency module according to claim 4, further comprising:
a pad electrode provided on the first main surface of the mounting substrate and connected to the ground layer,
wherein the bonding wire further includes a second end portion different from the first end portion, and
the second end portion of the bonding wire is connected to the pad electrode.

6. The high frequency module according to claim 5,
wherein the pad electrode disposed on the first main surface of the mounting substrate, an outer electrode of a predetermined electronic component disposed on the first main surface of the mounting substrate and different from the first electronic component, the second electronic component, and the third electronic component, or a shielding metal wall provided on the first main surface of the mounting substrate.

7. The high frequency module according to claim 1, further comprising:
a first top surface shield electrode provided on a main surface on a side opposite to a side of the mounting substrate in the third electronic component and connected to a first side surface shield electrode which is the side surface shield electrode;
a fourth electronic component disposed between the first electronic component and the second electronic component on the first main surface of the mounting substrate and adjacent to the third electronic component;
a second side surface shield electrode provided on at least one side surface of the fourth electronic component and connected to the ground layer;
a second top surface shield electrode provided on a main surface on a side opposite to the side of the mounting substrate in the fourth electronic component and connected to the second side surface shield electrode; and
a bonding wire having a first end portion and a second end portion,
wherein the first end portion of the bonding wire is connected to the first top surface shield electrode or the second top surface shield electrode, and
the second end portion of the bonding wire is connected to a pad electrode provided between the third electronic component and the fourth electronic component on the first main surface of the mounting substrate.

8. The high frequency module according to claim 1, further comprising:
a first top surface shield electrode provided on a main surface on a side opposite to a side of the mounting substrate in the third electronic component and connected to a first side surface shield electrode which is the side surface shield electrode;
a fourth electronic component disposed between the first electronic component and the second electronic component on the first main surface of the mounting substrate and adjacent to the third electronic component;
a second side surface shield electrode provided on at least one side surface of the fourth electronic component and connected to the ground layer;
a second top surface shield electrode provided on a main surface on a side opposite to the side of the mounting substrate in the fourth electronic component and connected to the second side surface shield electrode; and
a bonding wire having a first end portion and a second end portion,
wherein the first end portion of the bonding wire is connected to the first top surface shield electrode, and
the second end portion of the bonding wire is connected to the second top surface shield electrode.

9. The high frequency module according to claim 1, further comprising:
a resin provided on the first main surface to cover the first electronic component, the second electronic component, the third electronic component, and the side surface shield electrode;
an outer shield electrode provided on at least an outer surface of the resin and connected to the ground layer;
a top surface shield electrode provided on a main surface on a side opposite to a side of the mounting substrate in the third electronic component and connected to the side surface shield electrode; and
a bonding wire having a first end portion and a second end portion,
wherein the outer shield electrode has a plurality of side surface portions provided on a plurality of side surfaces of the resin,
the third electronic component is adjacent to one side surface portion of the plurality of side surface portions,
the first end portion of the bonding wire is connected to the top surface shield electrode provided in the third electronic component, and
the second end portion of the bonding wire is connected to the one side surface portion of the outer shield electrode.

10. The high frequency module according to claim 1, further comprising:
a fourth electronic component disposed between the first electronic component and the second electronic component on the first main surface of the mounting substrate and adjacent to the third electronic component; and
a bonding wire provided between the third electronic component and the fourth electronic component on the first main surface of the mounting substrate,
wherein both ends of the bonding wire are connected to pad electrodes provided between the third electronic component and the fourth electronic component on the first main surface of the mounting substrate and connected to the ground layer.

11. The high frequency module according to claim 1,
wherein the third electronic component includes a piezoelectric substrate.

12. The high frequency module according to claim 2,
wherein the resin includes a through hole that exposes a predetermined region of a main surface of the side surface shield electrode of the third electronic component, and
the outer shield electrode further covers an inner peripheral surface of the through hole and the predetermined region of the side surface shield electrode and is connected to the side surface shield electrode by coming into contact with the predetermined region.

13. A communication device comprising:
a high frequency including
a mounting substrate having a first main surface and a second main surface which face each other;
a first electronic component disposed on the first main surface of the mounting substrate, the first electronic component being one of a first filter, a first amplifier, or a first matching circuit;
a second electronic component disposed on the first main surface of the mounting substrate, the second electronic component being a second filter, a second amplifier, or a second matching circuit;
a third electronic component disposed between the first electronic component and the second electronic component on the first main surface of the mounting substrate, the third electronic component being an acoustic wave filter; and
a side surface shield electrode provided on at least one side surface of the third electronic component,
wherein the mounting substrate includes a ground layer, and
the side surface shield electrode is connected to the ground layer; and
a signal processing circuit connected to the high frequency module to perform signal processing on a high frequency signal.

14. The communication device of claim 13, further comprising:
a resin provided on the first main surface of the mounting substrate to cover the first electronic component, the second electronic component, the third electronic component, and the side surface shield electrode; and
an outer shield electrode provided on at least an outer surface of the resin and connected to the ground layer,
wherein the side surface shield electrode is connected to the outer shield electrode.

15. The communication device of claim 14, further comprising:
a top surface shield electrode provided on a main surface on a side opposite to a side of the mounting substrate in the third electronic component and connected to the side surface shield electrode; and
a recessed conductor layer that connects the top surface shield electrode and the outer shield electrode.

16. The communication device of claim 14, further comprising:
a top surface shield electrode provided on a main surface on a side opposite to a side of the mounting substrate in the third electronic component and connected to the side surface shield electrode; and
a bonding wire,
wherein the bonding wire has a first end portion and a predetermined portion which is a portion different from the first end portion,
the first end portion of the bonding wire is connected to the top surface shield electrode, and
the predetermined portion of the bonding wire is connected to the outer shield electrode.

17. The communication device of claim 16, further comprising:
a pad electrode provided on the first main surface of the mounting substrate and connected to the ground layer,
wherein the bonding wire further includes a second end portion different from the first end portion, and
the second end portion of the bonding wire is connected to the pad electrode.

18. The communication device of claim 17, wherein the pad electrode disposed on the first main surface of the mounting substrate, an outer electrode of a predetermined electronic component disposed on the first main surface of the mounting substrate and different from the first electronic component, the second electronic component, and the third electronic component, or a shielding metal wall provided on the first main surface of the mounting substrate.

19. The communication device of claim 13, further comprising:
a first top surface shield electrode provided on a main surface on a side opposite to a side of the mounting substrate in the third electronic component and connected to a first side surface shield electrode which is the side surface shield electrode;
a fourth electronic component disposed between the first electronic component and the second electronic component on the first main surface of the mounting substrate and adjacent to the third electronic component;
a second side surface shield electrode provided on at least one side surface of the fourth electronic component and connected to the ground layer;
a second top surface shield electrode provided on a main surface on a side opposite to the side of the mounting substrate in the fourth electronic component and connected to the second side surface shield electrode; and
a bonding wire having a first end portion and a second end portion,
wherein the first end portion of the bonding wire is connected to the first top surface shield electrode or the second top surface shield electrode, and
the second end portion of the bonding wire is connected to a pad electrode provided between the third electronic component and the fourth electronic component on the first main surface of the mounting substrate.

20. The communication device of claim 13, further comprising:
a first top surface shield electrode provided on a main surface on a side opposite to a side of the mounting substrate in the third electronic component and connected to a first side surface shield electrode which is the side surface shield electrode;
a fourth electronic component disposed between the first electronic component and the second electronic component on the first main surface of the mounting substrate and adjacent to the third electronic component;
a second side surface shield electrode provided on at least one side surface of the fourth electronic component and connected to the ground layer;
a second top surface shield electrode provided on a main surface on a side opposite to the side of the mounting substrate in the fourth electronic component and connected to the second side surface shield electrode; and
a bonding wire having a first end portion and a second end portion,
wherein the first end portion of the bonding wire is connected to the first top surface shield electrode, and
the second end portion of the bonding wire is connected to the second top surface shield electrode.
